(19) United States
(12) Patent Application Publication
(10) Pub. No.: US 2026/0025990 A1
(43) Pub. Date: Jan. 22, 2026

(54) MEMORY DEVICE AND FABRICATION METHOD THEREOF

(71) Applicant: YANGTZE MEMORY TECHNOLOGIES CO., LTD., Wuhan (CN)

(72) Inventors: Hao Zhang, Wuhan (CN); Gang Zhang, Wuhan (CN); Kuan Dong, Wuhan (CN); Longdong Liu, Wuhan (CN); Meng Xiao, Wuhan (CN); Liheng Liu, Wuhan (CN); Zongliang Huo, Wuhan (CN)

(21) Appl. No.: 18/935,209

(22) Filed: Nov. 1, 2024

(30) Foreign Application Priority Data
Jul. 22, 2024 (CN) 202410986579.7

(51) Int. Cl. H10B 41/20; H10B 41/35; H10B 43/20; H10B 43/35

(52) U.S. Cl. CPC H10B 41/20; H10B 41/35; H10B 43/20; H10B 43/35

(57) ABSTRACT

According to one aspect of the present disclosure, a memory device is provided. The memory device may include a first stack structure including a plurality of first gate layers and a plurality of first dielectric layers stacked alternately in a first direction. The memory device may include a second stack structure including a plurality of second gate layers and a plurality of second dielectric layers stacked alternately in the first direction. The memory device may include a plurality of connection structures including a connection post, at least one first connection layer and at least one second connection layer. The connection post may be located on a side of the first stack structure and the second stack structure in a second direction crossing the first direction.

### CROSS-REFERENCE TO RELATED APPLICATIONS

The present application claims the benefit of priority to Chinese Application No. 202410986579.7, filed on Jul. 22, 2024, which is hereby incorporated by reference in its entirety.

### TECHNICAL FIELD

The present disclosure relates to the technical field of semiconductor chips, and in particular to a memory device and a fabrication method thereof.

### BACKGROUND

As a feature size of a memory cell approaches a lower limit of a process, a planar process and fabrication technique become challenging and costly. As a result, the memory density for 2D or planar NAND flash memory approaches an upper limit.

In order to overcome the limitations of the 2D or planar NAND flash memory, a memory having a three-dimensional structure (a 3D NAND memory) has been developed in the industry to increase the memory density by disposing memory cells in three dimensions over a substrate.

### SUMMARY

According to one aspect of the present disclosure, a memory device is provided. The memory device may include a first stack structure including a plurality of first gate layers and a plurality of first dielectric layers stacked alternately in a first direction. The memory device may include a second stack structure including a plurality of second gate layers and a plurality of second dielectric layers stacked alternately in the first direction. The second stack structure and the first stack structure may be stacked in the first direction. The memory device may include a plurality of connection structures including a connection post, at least one first connection layer and at least one second connection layer. The connection post may be located on a side of the first stack structure and the second stack structure in a second direction crossing the first direction. The first connection layer may be parallel to the second direction. One of the at least one first connection layer connects the connection post with one of the first gate layers. The second connection layer may be parallel to the second direction. One of the at least one second connection layer connects the connection post with one of the second gate layers. In a reference plane parallel to the second direction, at least two of the connection structures may have their respective connection posts of different sizes.

In some implementations, the memory device may further include a channel structure extending through the first stack structure and the second stack structure. In some implementations, the size of the connection post may be larger than that of the channel structure in the reference plane.

In some implementations, the first stack structure may include a first stack substructure and a second stack substructure stacked in the first direction. In some implementations, the channel structure may include a first channel structure and a second channel structure stacked in the first direction with the first channel structure extending through the first stack substructure and the second channel structure extending through the second stack substructure.

In some implementations, the memory device may include a third stack structure and a fourth stack structure that are stacked in the first direction and located on a side of the first stack structure and the second stack structure in the second direction. In some implementations, the connection post may extend through the third stack structure and the fourth stack structure. In some implementations, the third stack structure may include a plurality of third dielectric layers and a plurality of fourth dielectric layers stacked alternately in the first direction with at least one of the third dielectric layers connected with the at least one first connection layer. In some implementations, the fourth stack structure may include a plurality of fifth dielectric layers and a plurality of sixth dielectric layers stacked alternately in the first direction with at least one of the fifth dielectric layers connected with the at least one second connection layer.

In some implementations, the memory device may further include a plurality of first isolation layers. In some implementations, one of the first isolation layers may extend partially through the third stack structure to one of the at least one first connection layer and surrounds one of the connection posts. In some implementations, a plurality of second isolation layers. In some implementations, one of the second isolation layers may extend partially through the fourth stack structure to one of the at least one second connection layer and surrounds one of the connection posts.

In some implementations, one of the plurality of connection structures may be a first connection structure and another one of the plurality of connection structures may be a second connection structure. In some implementations, in the first direction, the largest size of the first isolation layer surrounding the first connection structure may be larger than the largest size of the first isolation layer surrounding the second connection structure, and in the reference plane, the size of the connection post of the first connection structure may be larger than the size of the connection post of the second connection structure.

In some implementations, one of the plurality of connection structures may be a first connection structure and another one of the plurality of connection structures may be a second connection structure. In some implementations, in the first direction, the largest size of the first isolation layer surrounding the first connection structure may be larger than the largest size of the first isolation layer surrounding the second connection structure, and in the reference plane, the size of the connection post of the first connection structure may be smaller than the size of the connection post of the second connection structure.

In some implementations, in the reference plane, a size of the first isolation layer surrounding the first connection structure may be larger than a size of the first isolation layer surrounding the second connection structure.

In some implementations, one of the plurality of connection structures may be a third connection structure, and the first connection structure, the third connection structure and the second connection structure may be arranged in this order in a reference direction crossing the first direction. In some implementations, in the reference plane, the size of the connection post of the first connection structure may be larger than the size of the connection post of the third connection structure and the size of the connection post of the second connection structure may be larger than the size of the connection post of the third connection structure.

In some implementations, one of the plurality of connection structures may be a third connection structure, and the first connection structure, the third connection structure and the second connection structure may be arranged in this order in a reference direction crossing the first direction. In some implementations, in the reference plane, the size of the connection post of the first connection structure may be smaller than the size of the connection post of the third connection structure and the size of the connection post of the second connection structure may be smaller than the size of the connection post of the third connection structure.

In some implementations, the connection post may include a first connection post and a second connection post stacked in the first direction, the first connection post may extend through the third stack structure, and the second connection post may extend through the fourth stack structure. In some implementations, in the second direction, a size of an end of the first connection post proximate to the second connection post may be larger than a size of an end of the second connection post proximate to the first connection post.

In some implementations, in the second direction, the size of the end of the first connection post proximate to the second connection post may be larger than a size of an end of the first connection post away from the second connection post. In some implementations, in the second direction, a size of an end of the second connection post away from the first connection post may be larger than the size of the end of the second connection post proximate to the first connection post.

In some implementations, the first connection layer may include a first sublayer and a second sublayer stacked in the first direction with the first sublayer located between the first isolation layer and the second sublayer and the first isolation layer surrounding the first sublayer.

In some implementations, the first isolation layer may include a first isolation sublayer, a second isolation sublayer and a third isolation sublayer. In some implementations, the first isolation sublayer surrounds the connection post. In some implementations, the second isolation sublayer may be located between the first isolation sublayer and the connection post and surrounds the connection post. In some implementations, the third isolation sublayer may be located between the second isolation sublayer and the connection post and surrounds the connection post.

In some implementations, the first connection structure may further include a third isolation layer and a fourth isolation layer. In some implementations, the third isolation layer may be located on a side of the first connection layer away from the first isolation layer, and the third isolation layer may be in contact with the first connection post and surrounds the first connection post. In some implementations, the fourth isolation layer may be located on a side of the second connection layer away from the second isolation layer, and the fourth isolation layer may be in contact with the second connection post and surrounds the second connection post.

In some implementations, the memory device may further include a first select gate located on a side of the first stack structure away from the second stack structure. In some implementations, the memory device may further include a second select gate located on a side of the first stack structure proximate to the second stack structure. In some implementations, the memory device may further include a third select gate located on a side of the second stack structure proximate to the first stack structure. In some implementations, the memory device may further include a fourth select gate located on a side of the second stack structure away from the first stack structure. In some implementations, the memory device may further include a fourth connection structure located on a side of the first stack structure and the second stack structure in the second direction. In some implementations, one of the first select gate, the second select gate, the third select gate and the fourth select gate may be connected with the fourth connection structure.

In some implementations, the memory device may further include a first bit line and a second bit line. In some implementations, the first bit line may be located on a side of the first select gate away from the first stack structure, and the second bit line may be located on a side of the fourth select gate away from the second stack structure. In some implementations, an extending direction of the first bit line and the second bit line crosses the first direction.

In some implementations, the memory device may further include a third bit line. In some implementations, the third bit line may be located between the second select gate and the third select gate and has an extending direction crossing the first direction.

According to another aspect of the present disclosure, a method of fabricating a memory device is provided. The method may include forming a first stack structure and a second stack structure. The first stack structure may include a plurality of first gate layers and a plurality of first dielectric layers stacked alternately in a first direction and the second stack structure may include a plurality of second gate layers and a plurality of second dielectric layers stacked in the first direction with the second stack structure and the first stack structure stacked in the first direction. The method may include forming a plurality of connection structures including a connection post, at least one first connection layer and at least one second connection layer. The connection post may be located on a side of the first stack structure and the second stack structure in a second direction crossing the first direction. The first connection layer may be parallel to the second direction. One of the at least one first connection layer connects the connection post with one of the first gate layers. The second connection layer may be parallel to the second direction. One of the at least one second connection layer connects the connection post with one of the second gate layers. The method may include, in a reference plane parallel to the second direction, at least two of the connection structures have their respective connection posts of different sizes.

In some implementations, forming the first stack structure and the second stack structure may include forming a first deck structure having a first region including a plurality of first sacrificial layers and the plurality of first dielectric layers stacked alternately in the first direction and a second region that adjoins the first region and may be on a side of the first region of the first deck structure in the second direction crossing the first direction. In some implementations, forming the first stack structure and the second stack structure may include removing a part of the first deck structure to form a plurality of first connection holes located in the second region of the first deck structure. In some implementations, forming the first stack structure and the second stack structure may include forming a second deck structure stacked with the first deck structure in the first direction and having a first region including a plurality of second sacrificial layers and the plurality of second dielectric layers stacked alternately in the first direction and a second region that adjoins the first region and may be on a side of the first region of the second deck structure in the second direction. In some implementations, forming the first stack structure and the second stack structure may include removing a part of the second deck structure to form a plurality of second connection holes extending through the second region of the second deck structure. In some implementations, one of the second connection holes and one of the first connection holes together may form one connection hole. In some implementations, forming the first stack structure and the second stack structure may include replacing the first sacrificial layers with the first gate layers and replacing the second sacrificial layers with the second gate layers.

In some implementations, forming the first deck structure may include forming a first deck substructure having a first region including the plurality of first sacrificial layers and the plurality of first dielectric layers stacked alternately in the first direction and a second region that adjoins the first region and may be on a side of the first region of the first deck substructure in the second direction. In some implementations, forming the first deck structure may include removing a part of the first deck substructure to form a first channel hole extending through the first region of the first deck substructure. In some implementations, forming the first deck structure may include forming an etch stop layer stacked with the first channel hole in the first direction. In some implementations, forming the first deck structure may include forming a second deck substructure stacked with the first deck substructure in the first direction and having a first region including the plurality of first sacrificial layers and the plurality of first dielectric layers stacked alternately in the first direction and a second region that adjoins the first region and may be on a side of the first region of the second deck substructure in the second direction. In some implementations, the first deck substructure and the second deck substructure together may form the first deck structure.

In some implementations, after forming the first deck structure and before removing the part of the first deck structure, the method may further include forming a first isolation layer extending partially through the second region of the first deck structure in the first direction. In some implementations, removing the part of the first deck structure may include further removing a part of the first isolation layer to form the plurality of first connection holes and a second channel hole. In some implementations, the second channel hole may extend through the second deck substructure to the etch stop layer.

In some implementations, after forming the plurality of first connection holes and the second channel hole and before forming the second deck structure, the method may further include removing the etch stop layer to make the first channel hole and the second channel hole be in communication with each other.

In some implementations, forming the first isolation layer may include forming a first recess located in the second region of the first deck structure and extending partially through the first deck structure in the first direction. In some implementations, the second region of the first deck structure may include a plurality of third dielectric layers and a plurality of fourth dielectric layers stacked alternately in the first direction, at least one of the third dielectric layers may be connected with the first sacrificial layer, and the first recess may extend to the third dielectric layer. In some implementations, forming the first isolation layer may include forming a first isolation sublayer covering a sidewall of the first recess. In some implementations, forming the first isolation layer may include forming a second isolation sublayer that covers a bottom of the first recess and may be in contact the third dielectric layer and also covers a side of the first isolation sublayer. In some implementations, forming the first isolation layer may include forming a third isolation sublayer in the first recess, the third isolation sublayer covering the second isolation sublayer. In some implementations, the first isolation sublayer, the second isolation sublayer and the third isolation sublayer together may form the first isolation layer.

In some implementations, after forming the second deck structure and before removing the part of the second deck structure, the method may include forming a second recess located in the second region of the second deck structure and extending partially through the second deck structure in the first direction. In some implementations, the second region of the second deck structure may include a plurality of fifth dielectric layers and a plurality of sixth dielectric layers stacked alternately in the first direction, at least one of the fifth dielectric layers may be connected with the second sacrificial layer, and the second recess may extend to the fifth dielectric layer. In some implementations, after forming the second deck structure and before removing the part of the second deck structure, the method may include forming a fourth isolation sublayer covering a sidewall of the second recess. In some implementations, after forming the second deck structure and before removing the part of the second deck structure, the method may include forming a fifth isolation sublayer that covers a bottom of the second recess and the fourth isolation sublayer and may be in contact with the fifth dielectric layer. In some implementations, after forming the second deck structure and before removing the part of the second deck structure, the method may include forming a sixth isolation sublayer in the second recess, the sixth isolation sublayer covering the fifth isolation sublayer. In some implementations, the fourth isolation sublayer, the fifth isolation sublayer and the sixth isolation sublayer together may form a second isolation layer.

In some implementations, after forming the plurality of second connection holes and the second channel hole and before replacing the first sacrificial layers with the first gate layers, the method may further include forming a first channel structure in the first channel hole and a second channel structure in the second channel hole.

In some implementations, forming the plurality of connection structures may include removing a part of the second isolation sublayer at the bottom of the first recess and a part of the fifth isolation sublayer at the bottom of the second recess to form a first recess space in communication with the first connection hole and a second recess space in communication with the second connection hole. In some implementations, forming the plurality of connection structures may include removing a part of the third dielectric layer exposed in the first recess space and a part of the fifth dielectric layer exposed in the second recess space to form a first space to be filled in communication with the first recess space and a second space to be filled in communication with the second recess space. In some implementations, forming the plurality of connection structures may include filling a conductive material into the connection hole. In some implementations, a part of the conductive material filled in the connection hole may form the connection post, a part of the conductive material filled in the first space to be filled forms the first connection layer and a part of the conductive material filled in the second space to be filled forms the second connection layers.

In some implementations, removing the part of the second isolation sublayer at the bottom of the first recess and the part of the fifth isolation sublayer at the bottom of the second recess may include removing a part of the third dielectric layer and a part of the fifth dielectric layer to form a third recess space in communication with the first connection hole and a fourth recess space in communication with the second connection hole. In some implementations, removing the part of the second isolation sublayer at the bottom of the first recess and the part of the fifth isolation sublayer at the bottom of the second recess may include forming a third isolation layer in the third recess space and a fourth isolation layer in the fourth recess space.

### BRIEF DESCRIPTION OF DRAWINGS

In order to explain technical solutions of the present disclosure more clearly, accompanying drawings required by implementations of the present disclosure will be described briefly hereafter. It is obvious that the drawings to be described below are only for some implementations of the present disclosure and other drawings can be obtained according to those drawings by those skilled in the art. Moreover, the accompanying drawings to be described below may be considered as schematic diagrams and are not intended to limit an actual size of a product and an actual flow of a method involved in implementations of the present disclosure.

FIG. 1 is a schematic stereoscopic structure diagram of a memory device in accordance with some implementations;

FIG. 2 is a cross-sectional view of a memory device in accordance with some implementations;

FIG. 3 is a cross-sectional view of a memory cell string taken along the cut line A-A′ in the memory device shown in FIG. 1;

FIG. 4 is an equivalent circuit diagram of the memory cell string shown in FIG. 3;

FIG. 5 is a schematic circuit diagram of a memory device in accordance with some implementations;

FIG. 6 is a schematic structural diagram of a memory device in accordance with some implementations;

FIG. 7 is a schematic structural diagram of a memory device in a reference plane in accordance with some implementations;

FIG. 8 is a schematic structural diagram of a memory device in a reference plane in accordance with some other implementations;

FIG. 9 is a schematic circuit diagram of a memory device in accordance with some other implementations;

FIG. 10 is a flow chart of a fabrication method of a memory device in accordance with some implementations;

FIGS. 11-24 are schematic structural diagrams of a memory device during a fabrication process in accordance with some implementations;

FIG. 25 is a block diagram of a memory system in accordance with some implementations;

FIG. 26 is a block diagram of a memory system in accordance with some other implementations; and

FIG. 27 is a block diagram of an electronic apparatus in accordance with some implementations.

### DETAILED DESCRIPTION

The technical solutions in some implementations of the present disclosure will be described below clearly and fully with reference to accompanying drawings. However, it is obvious that the described implementations are a part of the present disclosure rather than all implementations of the present disclosure. All other implementations obtained by those skilled in the art based on the implementations provided in the present disclosure fall within the scope claimed by the present disclosure.

In the description of the present disclosure, it is understood that orientation and position relationships as indicated by terms “center”, “upper”, “lower”, “front”, “back”, “left”, “right”, “vertical”, “horizontal”, “top”, “bottom”, “inner”, “outer” or the like are those based on the drawings, and they are used only for the purpose of facilitating and simplifying the description of the present disclosure, and are not intended to indicate or imply that the described devices or elements must have any particular orientation, or be constructed or operated in any particular orientation. As a result, they should not be understood as any limitation on the present disclosure.

In the whole specification and claims, the term “include” or “comprise” should be interpreted to be open and inclusive, i.e. to have the meaning of “include or comprise, but not limited to”, unless indicated otherwise in the context. In the description of the specification, terms “one implementation”, “some implementations”, “example implementations”, “in an example” or “some examples” are intended to mean that specific features, structures, materials or characteristics related to the implementation(s) or example(s) are included in at least one implementation or example of the present disclosure. The above-mentioned terms may not necessarily refer to one and the same implementation or example. Moreover, the specific features, structures, materials or characteristics may be included in one or more implementations or examples in any suitable way.

Hereafter, the terms “first”, “second”, or the like are only used for the purpose of description and should not be understood to indicate or imply relative importance or to designate the number of the referenced technical features implicitly. Therefore, a feature as defined by “first” or “second” may indicate explicitly or implicitly that one or more instances of the feature may be included. In description of implementations of the present disclosure, the expression “a plurality of” means two or more unless otherwise specified.

In description of some implementations, terms “couple” and “connect” as well as their derivative expressions may be used. For example, in description of some implementations, the term “connect” may be used to indicate that two or more components are direct/indirect physical or electrical contact with each other. For another example, in description of some implementations, the term “couple” may be used to indicate that two or more components are in direct physical or electrical contact. However, the term “couple” may also indicate that two or more components are not in direction contact with each other, but still cooperate or interact with each other. Implementations disclosed herein are not necessarily limited to the contents provided herein.

“At least one of A, B and C” and “at least one of A, B or C” have the same meaning and both include the following combinations of A, B and C: only A; only B; only C; a combination of A and B; a combination of A and C; a combination of B and C; and a combination of A, B and C.

“A and/or B” includes the following three combinations: only A, only B, and a combination of A and B.

The expression “adapted for” or “configured to” as used herein has an open and inclusive meaning and is not intended to exclude that a device is adapted for performing additional tasks or operations or is configured to perform additional tasks or operations.

In addition, the expression “based on” as used herein has an open and inclusive meaning, because a process, an operation, a calculation or any other action “based on” one or more conditions or values may further be based on additional conditions or other values in practice.

As used herein, the expression “about”, “nearly” or “approximately” includes the stated value together with a mean value of a certain value having an acceptable deviation range, wherein the acceptable deviation range is determined by those of ordinary skill in the art considering the measurements under discussion and errors related to measurements of a certain quantity, namely limitations of the measurement system.

In the present disclosure, the meanings of the expressions “on”, “over” and “above” should be interpreted in the broadest manner such that “on” not only means “directly on” something but also includes the meaning of “on” something with an intermediate feature or a layer therebetween, and “over” or “above” not only means the meaning of “over” or “above” something but can also include the meaning it is “above” or “over” something with no intermediate feature or layer therebetween (i.e., directly on something).

Example implementations are described herein with reference to sectional views and/or plan views as ideal illustrative drawings. In the figures, thicknesses of layers and regions are exaggerated for clarity. Therefore, it can be appreciated that the deviation from a shape shown in the figures may be due to, for example, manufacturing processes and/or tolerances. Therefore, example implementations should not be interpreted to be limited to the shapes of the regions as shown, but include the deviation in the shapes due to, for example, manufacturing. For example, an etched region of a rectangular shape usually has a curved feature. Therefore, the regions as shown in the figures are illustrative in nature, and their shapes are not intended to depict actual shapes of regions of a device and also not intended to limit the scope of example implementations.

As used herein, the term “substrate” refers to a material onto which subsequent material layers may be added. The substrate may be patterned itself. Materials added on top of the substrate can be patterned or can remain unpatterned. Furthermore, the substrate may include a wide array of semiconductor materials, such as silicon, germanium, gallium arsenide, indium phosphide, etc. Alternatively, the substrate may be made of an electrically non-conductive material, such as a glass, plastic or sapphire wafer.

As used herein, “parallel”, “perpendicular” or “equal” includes the stated instance and the instances similar thereto having an acceptable deviation range, wherein the acceptable deviation range is determined by those of ordinary skill in the art considering the measurements under discussion and errors related to measurements of a certain quantity, namely limitations of the measurement system. For example, the term “parallel” may include the meaning of “absolutely parallel” and “approximately parallel”, and the “approximately parallel” may have an acceptable deviation range that is, for example, within 5°; the term “perpendicular” may include the meaning of “absolutely perpendicular” and “approximately perpendicular”, and the “approximately perpendicular” may have an acceptable deviation range that is also, for example, within 5°. The term “equal” may include the meaning of “absolutely equal” and “approximately equal”, and the “approximately equal” may have an acceptable deviation range which may be that the difference between the two values, which can be said to be equal to each other, is smaller than or equal to 5% of either one of them.

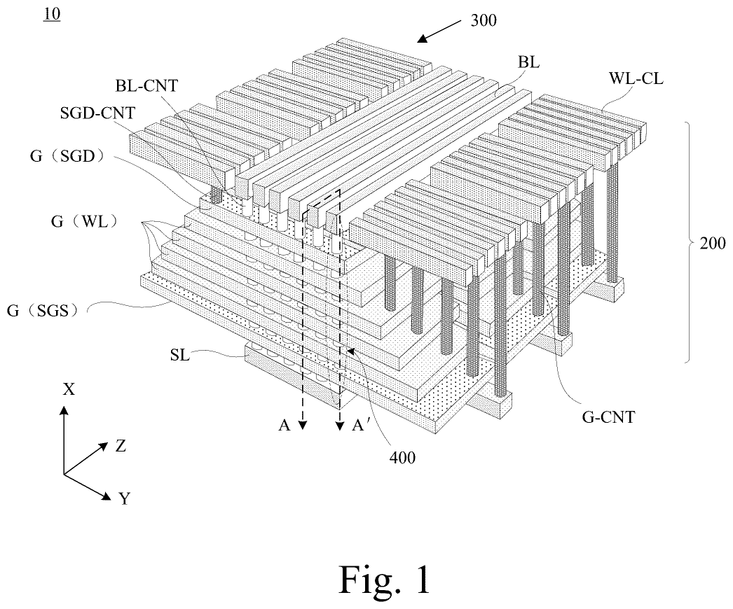

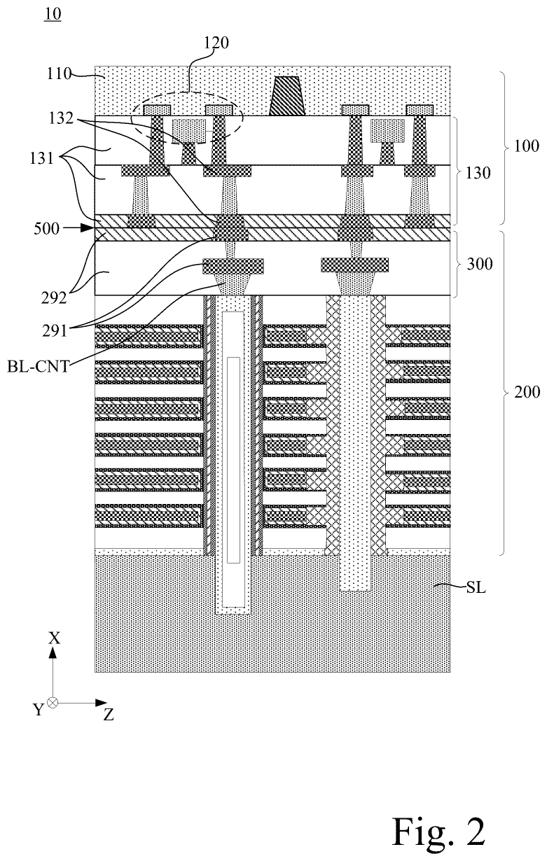

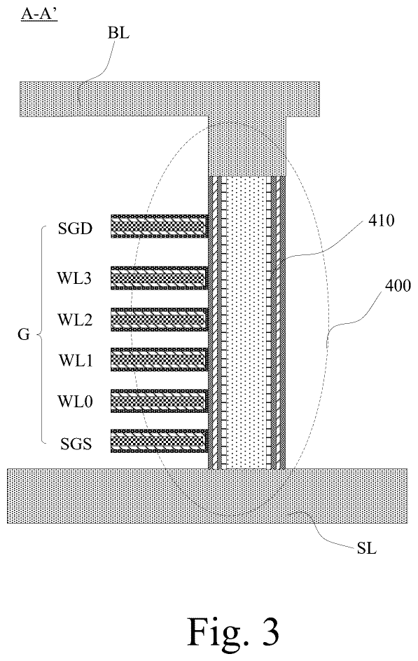

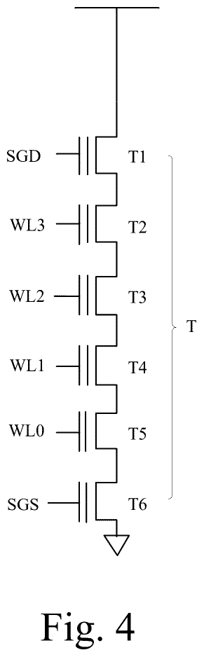

FIG. 1 is a schematic stereoscopic structure diagram of a memory device in accordance with some implementations, FIG. 2 is a cross-sectional view of a memory device in accordance with some implementations, FIG. 3 is a cross-sectional view of a memory cell string taken along the cut line A-A′ in the memory device shown in FIG. 1, and FIG. 4 is an equivalent circuit diagram of the memory cell string shown in FIG. 3.

Referring to FIGS. 1 and 2, a memory device 10 provided in some implementations of the present disclosure is located in a three-dimensional (i.e., X-Y-Z) coordinate system. The memory device 10 extends in a Y-Z plane. For example, the second direction Y is the extending direction of word lines WL and the third direction Z is the extending direction of bit lines BL. The first direction X is perpendicular to the Y-Z plane.

It is to be noted that the first direction X may cross the second direction Y, and the third direction Z may cross the X-Y plane. In the present disclosure, an example, in which the first direction X, the second direction Y and the third direction Z are perpendicular to each other, is used to explain structures as provided in some implementations of the present disclosure.

As used in the present disclosure, whether a component (e.g., a layer, structure or device) is located “on”, “over” or “under” another component (e.g., another layer, structure or device) in a semiconductor device (e.g., a memory device) is determined with respect to the source layer SL of the semiconductor device in the first direction X when the source layer SL is at the lowest plane of the semiconductor device in the first direction X. In the entire disclosure, the same notions are applied to describe spatial relationships.

Referring to FIGS. 1 and 2, some implementations of the present disclosure provide a memory device 10. The memory device 10 may include a semiconductor structure 200. The memory device 10 may further include a source layer SL coupled with the semiconductor structure 200 and a peripheral device 100 coupled with the semiconductor structure 200. The peripheral device 100 may be disposed on a side of the semiconductor structure 200 away from the source layer SL.

The source layer SL may include a semiconductor material, such as single crystal silicon, single crystal germanium, a III-V compound semiconductor material, a II-VI compound semiconductor material or any other suitable semiconductor material. The source layer SL may be doped partially or entirely. In an example, the source layer SL may include a doped region that is doped with a p-type dopant. The source layer SL may also include an undoped region.

The semiconductor structure 200 may further include memory cell transistor strings (hereafter referred to as “memory cell strings”, for example, NAND memory cell strings) arranged in an array. The source layer SL may be coupled with the source ends of a plurality of memory cell strings 400.

In an example, referring to FIGS. 3 and 4, a memory cell string 400 may include a plurality of transistors T. One transistor T (e.g., any one of T2-T5 in FIG. 4) may be configured as one memory cell and those transistors T are connected together to form the memory cell string 400. One transistor T (e.g., each transistor T) may be formed of a channel structure 410 and a gate line G surrounding the channel structure 410. Here, the gate line G may be configured to control the on/off state of the transistor.

It is to be noted that the numbers of transistors in FIGS. 1 to 4 are only illustrative, and the memory cell string 400 of the memory device 10 provided in implementations of the present disclosure may also include any other number of transistors, for example, 4, 16, 32 or 64.

Further, along the first direction X, the lowermost gate line of a plurality of gate lines G (e.g., the gate line of the plurality of gate lines closest to the source layer SL) may be constructed as a source end select gate SGS that is configured to control the on/off state of a transistor T6 and thus the on/off state of the channel at the source end of the memory cell string 400. Along the first direction X, the uppermost gate line of the plurality of gate lines G (e.g., the gate line of the plurality of gate lines furthest from the source layer SL) may be constructed as a drain end select gate SGD that is configured to control the on/off state of a transistor T1 and thus the on/off state of the channel at the drain end of the memory cell string 400. The middle gate lines of the plurality of gate lines G may be constructed as a plurality of word lines WL including, for example, a word line WL0, a word line WL1, a word line WL2 and a word line WL3. By applying different voltages to the word lines WL, memory cells (e.g., transistors T) in the memory cell string 400 can be written, read and erased.

With continued reference to FIGS. 1 and 2, in some implementations, the semiconductor structure 200 may further include an array interconnection layer 300. The array interconnection layer 300 may be coupled with the memory cell strings 400. The array interconnection layer 300 may include drain ends of the memory cell strings 400 (i.e., bit lines BL) that are coupled with the semiconductor channels of respective transistors T in at least one memory cell string 400.

The array interconnection layer 300 may include one or more first interlayer insulating layers 292 and may further include a plurality of contacts, insulated from each other by the first interlayer insulating layers 292, including bit line contacts BL-CNT, drain end select gate contacts SGD-CNT and gate line contacts G-CNT. Here, the bit line contacts BL-CNT are coupled with bit lines BL, the drain end select gate contacts SGD-CNT are coupled with drain end select gates SGD, and the gate line contacts G-CNT are coupled with gate lines G.

The array interconnection layer 300 may further include one or more first interconnection conductor layers 291. The first interconnection conductor layer 291 may include a plurality of connecting lines, such as bit lines BL, and word line connecting lines WL-CL coupled with word lines WL. The first interconnection conductor layer 291 and the contacts may include conductive materials such as one of tungsten, cobalt, copper, aluminum and metal silicide or any combination thereof, or may also include any other conductive materials. The first interlayer insulating layer 292 may include an insulating material, such as one of silicon oxide, silicon nitride, and an insulating material having a high dielectric constant, or any combination thereof, or may include any other insulating material.

The peripheral device 100 may include a peripheral circuit. The peripheral circuit is configured to control and sense array devices. The peripheral circuit may be any suitable digital, analog, or mixed-signal control and sensing circuit for supporting operations (or functioning) of the array devices, including, but not limited to, a page buffer, a decoder (e.g., a row decoder and a column decoder), a sense amplifier, a driver (e.g., a word line driver), a charge pump, a current or voltage reference, or any active or passive component in the circuit (e.g., a transistor, a diode, a resistor or a capacitor). The peripheral circuit may also include any other circuit compatible with advanced logic processes including a logic circuit (e.g., a processor and a programmable logic device PLD) or a memory circuit (e.g., a static random access memory SRAM).

For example, in some implementations, the peripheral device 100 may include a substrate 110, transistors 120 disposed on the substrate 110 and a peripheral interconnection layer 130 disposed on the substrate 110. The peripheral circuit may include the transistors 120.

The material of the substrate 110 may be single crystal silicon or any other suitable material such as a thin film of silicon germanium, germanium or silicon on insulator.

The peripheral interconnection layer 130 is coupled with transistors 120 to enable transmission of electrical signals therebetween. The peripheral interconnection layer 130 may include one or more second interlayer insulating layers 131, and may further include one or more second interconnection conductor layers 132. Different second interconnection conductor layers 132 may be coupled with each other through contacts. The second interconnection conductor layers 132 and the contacts may include conductive materials such as one of tungsten, cobalt, copper, aluminum, and metal silicide, or any combination thereof, or may also include any other suitable material. The second interlayer insulating layers 131 may include an insulating material, for example, one of silicon oxide, silicon nitride, and an insulating material having a high dielectric constant, or any combination thereof, or may also include any other suitable material.

The peripheral interconnection layer 130 may be coupled with the array interconnection layer 300, so that the semiconductor structure 200 may be coupled with the peripheral device 100. In an example, since the peripheral interconnection layer 130 is coupled with the array interconnection layer 300, the peripheral circuit in the peripheral device 100 can be coupled with memory cell strings in the semiconductor structure 200 to enable transmission of electrical signals therebetween. In some possible implementations, a bonding interface 500 may be disposed between the peripheral interconnection layer 130 and the array interconnection layer 300. Through the bonding interface 500, the peripheral interconnection layer 130 and the array interconnection layer 300 may be bonded and coupled to each other.

Currently, users are in pursuit of a memory device having a larger capacity and a smaller volume. Referring to FIG. 1, in order to improve the capacity of the memory device 10, the number of the stacked layers of gate lines G is increased. However, one gate line G is connected with one gate line contact G-CNT. With the increased number of the layers of gate lines G, the number of the gate line contacts G-CNT coupled with the gate lines G is increased, and thus the area occupied by the gate line contacts G-CNT coupled with the gate lines G is also increased, so that the dimension of the memory device 10 in a second direction Y is increased, preventing the memory density of the memory device 10 from being increased and the volume of the memory device 10 from becoming smaller.

Moreover, the gate lines G are coupled with string driver (SD) devices through gate line contacts G-CNT. However, one gate line contact G-CNT is connected with one SD device, so that with the increased number of the gate line contacts G-CNT, the number of the SD devices is increased, and thus the area occupied by the SD devices is also increased, preventing the volume of the memory device 10 from becoming smaller.

Furthermore, with the increased number of the layers of gate lines G, the number of the SD devices is also increased. In order to control the dimensions of the memory device 10, how to reduce the dimensions of the SD devices is one problem to be solved in the art.

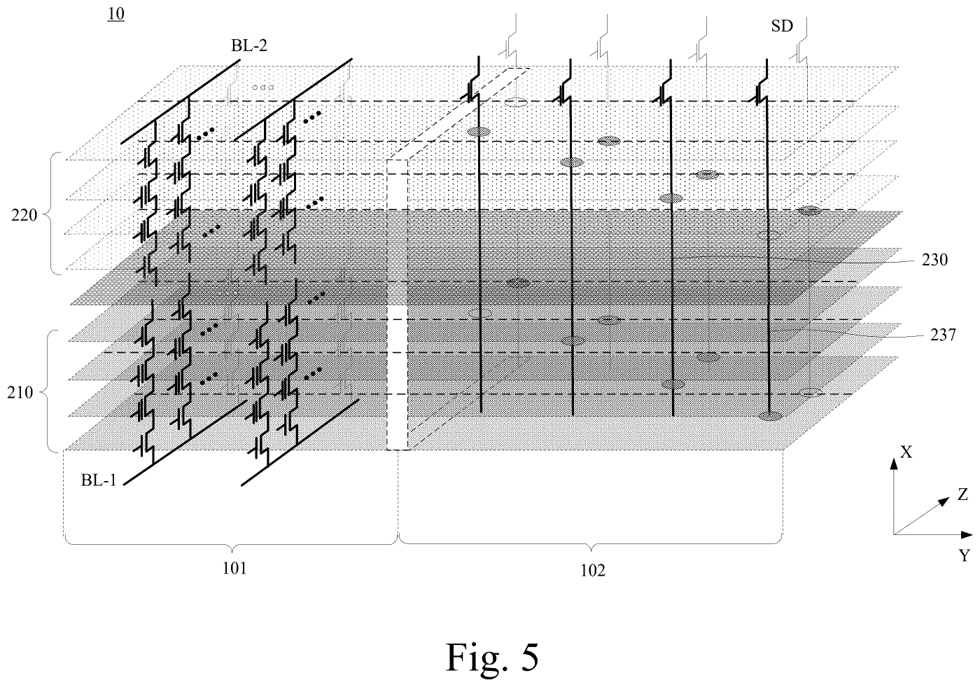

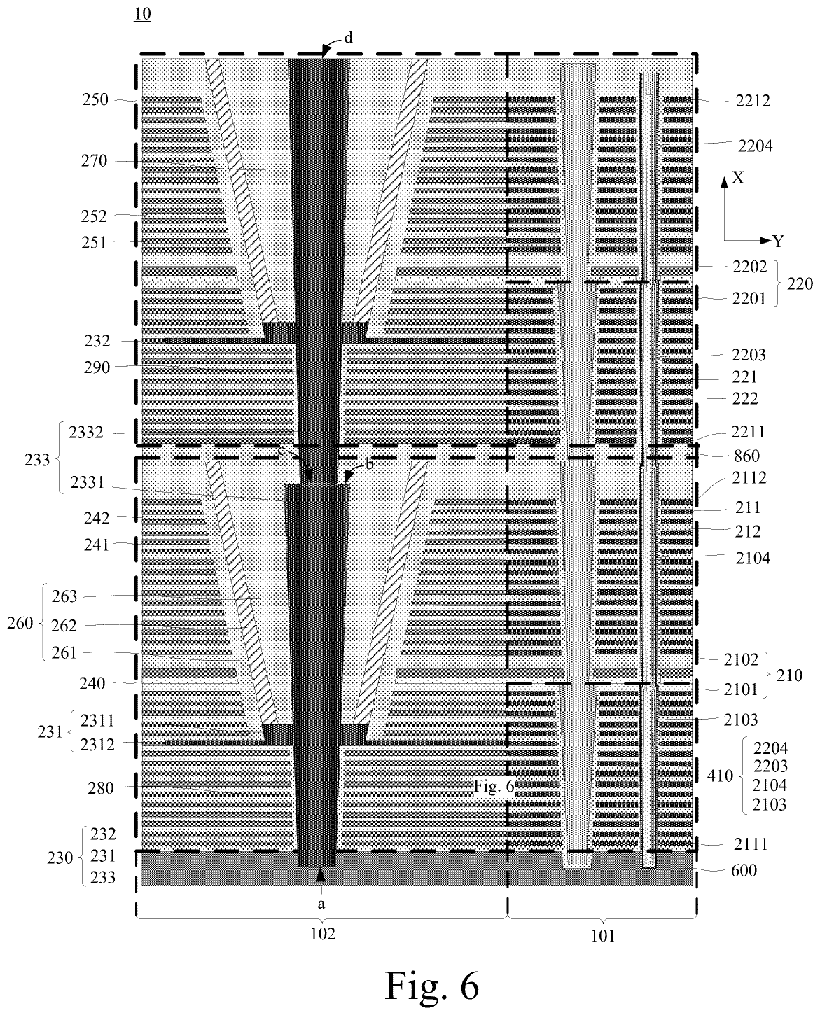

FIG. 5 is a schematic circuit diagram of a memory device in accordance with some implementations. FIG. 6 is a schematic structural diagram of a memory device in accordance with some implementations. As shown in FIGS. 5 and 6, the memory device 10 provided in some implementations of the present disclosure includes a first stack structure 210, a second stack structure 220, and a plurality of connection structures 230.

Here, the first stack structure 210 may be disposed on a semiconductor layer 600. In an example, the first stack structure 210 may be in direct contact with the semiconductor layer 600. In an example, the semiconductor layer 600 may include e.g., single crystalline silicon, single crystalline germanium, a III-V compound semiconductor material, a II-V compound semiconductor material, and any other suitable semiconductor material.

The first stack structure 210 includes a plurality of first gate layers 211 and a plurality of first dielectric layers 212 stacked alternately in the first direction X. For example, the first gate layers 211 and the first dielectric layers 212 are disposed and stacked alternately in the first direction X to form a plurality of first gate layers 211 spaced from each other and a plurality of first dielectric layers 212 spaced from each other. It may also be understood that one first gate layer 211 and one first dielectric layer 212 together constitute one gate structure pair. The first stack structure 210 includes a plurality of first gate structure pairs stacked in the first direction X.

In an example, the number of the first gate layers 211 may be 4, 16, 32, 64, 128, 256 or the like. The number of the first dielectric layers 212 may be 4, 16, 32, 64, 128, 256 or the like. A thickness of the first gate layer 211 (i.e., a dimension in the first direction X) may be approximately equal to or different from a thickness of the first dielectric layer 212. For example, the thickness of the first gate layer 211 may be larger than the thickness of the first dielectric layer 212.

In an example, the first gate layers 211 may include a conductive material, including, but not limited to, any one of tungsten (W), cobalt (Co), copper (Cu), aluminum (Al), polysilicon, doped silicon, silicide or any combination thereof, or may include any other suitable conductive material. In some examples, the first gate layer 211 includes a metal layer, for example, a layer of tungsten. In some examples, the first gate layer 211 includes a layer of doped polysilicon. A suitable dopant may be utilized to dope the polysilicon to a desired doping concentration, so that the polysilicon can be turned into a conductive material for the first gate layers 211.

In an example, the first dielectric layers 212 may include an insulating material, including any one of silicon oxide, silicon nitride, silicon oxynitride, and an insulating material with a high dielectric constant, or any combination thereof, or may also include any other suitable insulating material. Here, the dielectric constant of silicon oxynitride is higher than that of silicon oxide, and for example, ranges from 4 to 7 in an environment at about 20° C. In some examples, the first dielectric layer 212 includes a layer of silicon oxide. In some examples, the first dielectric layer 212 includes a layer of silicon oxynitride.

In an example, the thickness of the first gate layer 211 (i.e., a dimension along the first direction X) may be between 10 nm and 50 nm, for example, 10 nm, 15 nm, 18.3 nm, 20 nm, 25 nm, 27.7 nm, 30 nm, 35 nm, 40 nm, 45 nm, 50 nm, or the like. Similarly, the thickness of the first dielectric layer 212 (i.e., a dimension along the third direction Z) may be between 10 nm and 50 nm, for example, 10 nm, 15 nm, 18.3 nm, 20 nm, 25 nm, 27.7 nm, 30 nm, 35 nm, 40 nm, 45 nm, 50 nm, or the like. Here, the first gate layer 211 may be a gate line G (see FIG. 6) surrounding a memory cell string and serve as a world line WL (see FIG. 4) extending laterally, i.e. along the second direction Y.

The second stack structure 220 includes a plurality of second gate layers 221 and a plurality of second dielectric layers 222 stacked alternately in the first direction X. For example, the second gate layers 221 and the second dielectric layers 222 are disposed and stacked alternately in the first direction X to form the plurality of second gate layers 221 spaced from each other and the plurality of second dielectric layers 222 spaced from each other.

It can be understood that a reference can be made to the above examples of the constituent materials, thicknesses and numbers of the first gate layers 211 and the first dielectric layers 212 for those of the second gate layers 221 and the second dielectric layers 222. The constituent materials, thicknesses and number of the second gate layers 221 may be the same as or different from those of the first gate layers 211, and the constituent materials, thicknesses and number of the second dielectric layers 222 may be the same as or different from those of the first dielectric layers 212.

Moreover, as shown in FIG. 6, the second stack structure 220 and the first stack structure 210 are stacked along the first direction X. An isolating dielectric layer 860 is disposed between the first stack structure 210 and the second stack structure 220, and has a thickness in the first direction X far larger than that of the first dielectric layer 212 (or the second dielectric layer 222). In an example, the thickness of the isolating dielectric layer 860 in the first direction X may be in a range from 2 times to 10 times of the thickness of the first dielectric layer 212. For example, the thickness of the isolating dielectric layer 860 in the first direction X may be 2 times, 6 times or 10 times of the thickness of the first dielectric layer 212. When the thickness of the isolating dielectric layer 860 approximates 2 times of the thickness of the first dielectric layer 212, the spacing between the first stack structure 210 and the second stack structure 220 is relatively smaller, which is advantageous for an improvement in the memory density of the memory device 10. When the thickness of the isolating dielectric layer 860 approximates 10 times of the thickness of the first dielectric layer 212, which is advantageous for an improvement in the effects of isolation between the first stack structure 210 and the second stack structure 220.

The constituent material of the isolating dielectric layer 860 may be the same as that of the first dielectric layer 212 (or the second dielectric layer 222). In an example, the top layer of the first stack structure 210 (the layer in the first stack structure 210 that is the nearest to the second stack structure 220) may be a first dielectric layer 212. When forming the top-most first dielectric layer 212 of the first stack structure 210, the top-most first dielectric layer 212 may have an increased thickness, so as to isolate the first stack structure 210 from the second stack structure 220. Here, the top-most first dielectric layer 212 with an increased thickness may serve as the isolating dielectric layer 860 between the first stack structure 210 and the second stack structure 220. In an example, the bottom layer of the second stack structure 220 (the layer in the second stack structure 220 that is the nearest to the first stack structure 210) may be a second dielectric layer 222. When forming the bottom-most second dielectric layer 222 of the second stack structure 220, the bottom-most second dielectric layer 222 may have an increased thickness, so as to isolate the first stack structure 210 from the second stack structure 220. Here, the bottom-most second dielectric layer 222 with an increased thickness may serve as the isolating dielectric layer 860 between the first stack structure 210 and the second stack structure 220.

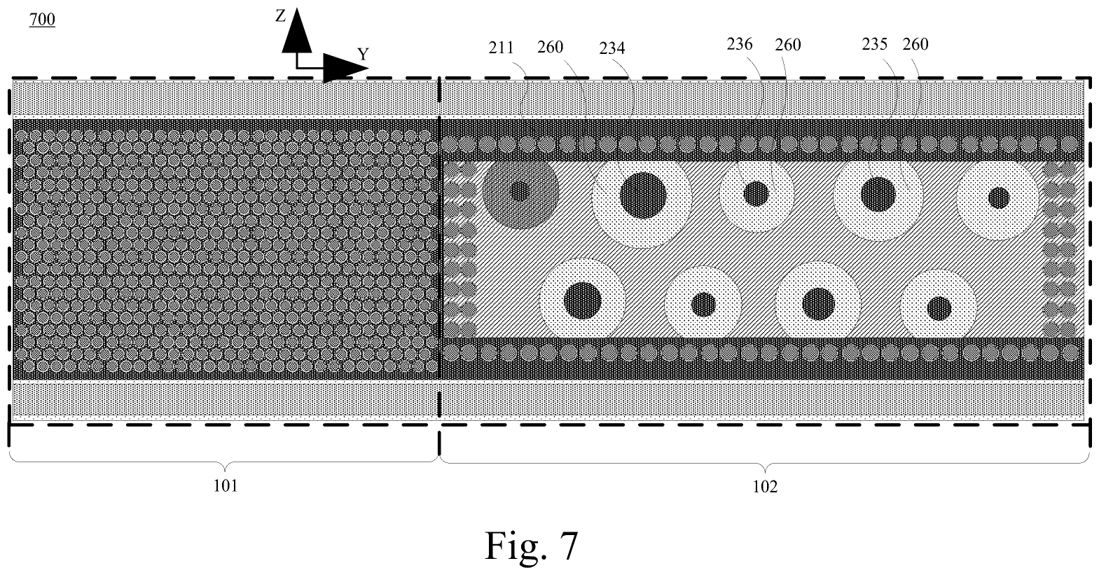

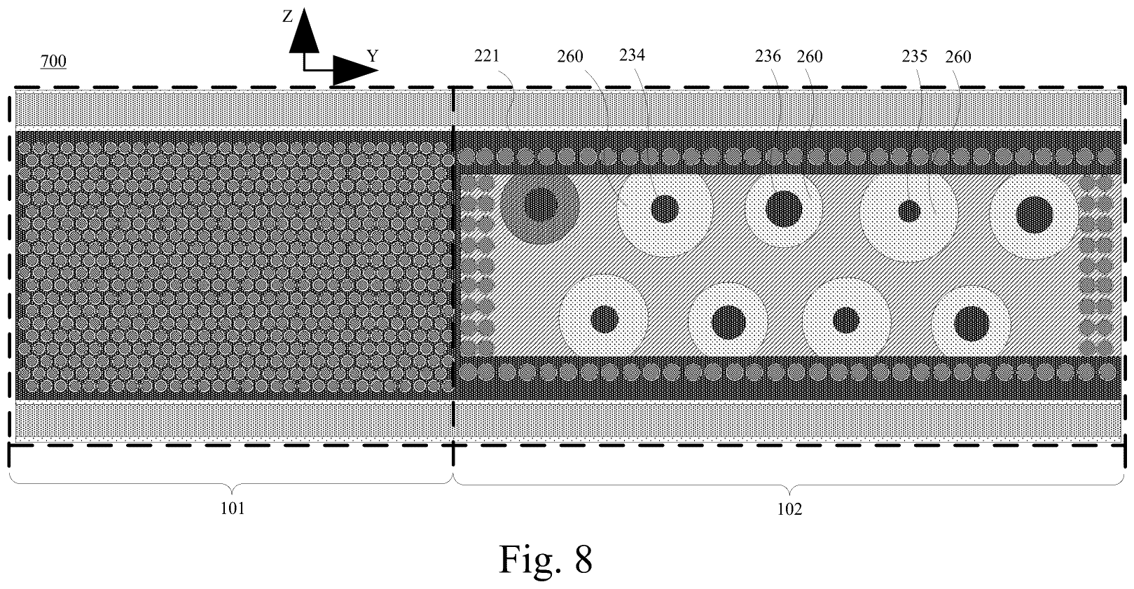

FIG. 7 is a schematic structural diagram of a memory device in a reference plane in accordance with some implementations; and FIG. 8 is a schematic structural diagram of a memory device in a reference plane in accordance with some other implementations. Referring to FIGS. 5, 6, 7 and 8, and in this implementation, the connection structure 230 includes a connection post 233, at least one first connection layer 231 and at least one second connection layer 232. Here, the connection post 233 is located on a side of the first stack structure 210 and the second stack structure 220 in the second direction Y. In an example, the memory device 10 may include a first region 101 and a second region 102 adjoining the first region 101 in the second direction Y. The first stack structure 210 and the second stack structure 220 may both be located within the first region 101, while the connection structure 230 may be located in the second region 102.

In this implementation, the first connection layer 231 may be parallel to the second direction Y and the third direction Z, and may be disposed to surround and be in connection with the connection post 233 in a Y-Z plane. One first connection layer 231 may be used to connect the connection post 233 with one first gate layer 211. Referring to FIG. 7, in this implementation, the first gate layer 211 may extend in the second direction Y, and for example, may extend to the second region 102 in the second direction Y, while the first connection layer 231 is parallel to the second direction Y and the third direction Z, and the first connection layer 231 in the second region 102 may be connected with a part of the first gate layer 211 that extends to the second region 102. For example, the first connection layer 231 and the first gate layer 211 may be connected to each other in the third direction Z. It is to be noted that the first connection layer 231 is used to connect the first gate layer 211 with the connection post 233, and a specific way, in which the first connection layer 231 and the first gate layer 211 are connected together, includes, but is not limited to, the one provided in this implementation. The present disclosure is not limited in this respect.

Referring to FIGS. 6 and 7, in a Y-Z plane, the cross section of the connection post 233 may be, for example, circular, and the cross section of the first connection layer 231 may be annular. The first connection layer 231 may surround and be connected with the connection post 233.

Likewise, the second connection layer 232 may be parallel to the second direction Y and the third direction Z, and may be disposed to surround and be in connection with the connection post 233 in a Y-Z plane. One second connection layer 232 connects the connection post 233 with one second gate layer 221. The second gate layer 221 may extend to the second region 102 in the second direction Y, while the second connection layer 232 is parallel to the second direction Y and the third direction Z and may be connected with a part of the second gate layer 221 that extends to the second region 102 in the second direction Y. For example, the second connection layer 232 and the second gate layer 221 may be connected to each other in the third direction Z. It is to be noted that the second connection layer 232 is used to connect the second gate layer 221 with the connection post 233 and a specific way, in which the second connection layer 232 and the second gate layer 221 are connected together, includes, but is not limited to, the one provided in this implementation. The present disclosure is not limited in this respect.

With continued reference to FIGS. 6 and 7, in a Y-Z plane, the cross section of the connection post 233 may be, for example, circular, and the cross section of the second connection layer 232 may be annular. The second connection layer 232 may surround and be connected with the connection post 233.

It is to be noted that the connection structure 230 includes at least one first connection layer 231 and at least one second connection layer 232. It can be understood that the connection structure 230 may include one first connection layer 231 or a plurality of first connection layers 231, and the connection structure 230 may include one second connection layer 232 or a plurality of second connection layers 232. When the connection structure 230 includes a plurality of first connection layers 231, the plurality of first connection layers 231 may be spaced from each other in the first direction X; and when the connection structure 230 includes a plurality of second connection layers 232, the plurality of second connection layers 232 may be spaced from each other in the first direction X. Implementations herein will be explained with an example connection structure 230, which includes one first connection layer 231 and one second connection layer 232.

The connection post 233 may extend in the first direction X and may be in connection with a SD device. A connection post 233, a first connection layer 231 and a second connection layer 232 together form a connection structure 230. In an example, the connection post 233, the first connection layer 231 and the second connection layer 232 may form a one-piece structure. It can be understood that the connection post 233, the first connection layer 231 and the second connection layer 232 may be fabricated in the same one process operation to advantageously improve reliability of electrical connection between the connection post 233 and the first connection layer 231 and electrical connection between the connection post 233 and the second connection layer 232. In this implementation, the connection structure 230 may include a conductive material including, but not limited to, any one of tungsten (W), cobalt (Co), copper (Cu), aluminum (Al), polysilicon, doped silicon, and silicide, or any combination thereof, or may also include any other suitable conductive material.

As shown in FIGS. 5 and 6, the connection structure 230 is connected with at least one first gate layer 211 and also with at least one second gate layer 221. For example, in FIG. 6, the connection structure 230 is connected with one first gate layer 211 in the first stack structure 210 and also with one second gate layer 221 in the second stack structure 220. An end of the connection post away from the semiconductor layer 600 may be connected with a SD device, which is then in electrical connection with at least one first gate layer 211 and at least one second gate layer 221 through the connection structure 230.

It is to be noted that the connection structure 230 being connected with at least one first gate layer 211 may be understood as that the connection structure 230 may be connected with one first gate layer 211 or with a plurality of first gate layers 211. The connection structure 230 being connected with at least one second gate layer 221 may be understood as that the connection structure 230 may be connected with one second gate layer 221 or with a plurality of second gate layers 221. This implementation will be explained with an example, in which the connection structure 230 is connected with one first gate layer 211 and with one second gate layer 221.

In some other implementations, in connection with FIGS. 1, 5 and 6, it can be seen that the individual gate layers may be led out through gate line contacts G-CNT in the memory device 10. For example, one first gate layer 211 is connected with one SD device through one gate line contact G-CNT and one second gate layer 221 is connected with one SD device through one gate line contact G-CNT. In this implementation, since a plurality of first gate layers and a plurality of second gate layers need to be led out through gate line contacts G-CNT respectively, that is, one gate layer needs to be led out through one gate line contact G-CNT, the number of the required gate line contacts G-CNT is relatively larger, and since one gate line contact G-CNT is connected with one SD device, the number of the required SD devices is relatively larger. A plurality of gate line contacts G-CNT are arranged stepwise, resulting in a relatively larger space occupied by the gate line contacts, and a relatively larger space is also be occupied by the relatively larger number of SD devices, prohibiting the memory density of the memory device 10 from being improved.

However, in this implementation, referring to FIGS. 5 and 6, one first gate layer 211 and one second gate layer 221 may share one connection structure 230 and one SD device. Then, when the memory device 10 has two stack structures (i.e., the first stack structure 210 and the second stack structure 220), as compared with the implementation, in which one first gate layer 211 is connected with one SD device through one gate line contact G-CNT and one second gate layer 221 is connected with one SD device through one gate line contact G-CNT, the number of the connection structures 230 in this implementation is smaller than the number of the gate line contacts G-CNT and the number of the SD devices in this implementation is also decreased accordingly, so that the space occupied by the connection structures 230 is smaller than the space occupied by the gate line contacts G-CNT and meanwhile the space occupied by the SD devices is also decreased, which is advantageous for improving the memory density of the memory device 10.

When the memory device 10 includes more stack structures, for example, 4, 6 or 8 stack structures, the connection structure 230 may be connected with one gate layer in each of the plurality of stack structures. With the above-described configuration, even if the number of the stack structures is increased, the number of the connection structures 230 and the space occupied by the connection structures 230 will not be increased, which is advantageous for the improvement in the memory density of the memory device 10 and the development of the memory device 10 towards a larger capacity and a smaller volume.

Furthermore, a problem is mentioned as above. That is, in order to improve the capacity of the memory device 10, the number of the stack structures is increased and thus the number of the SD devices is also increased, but in order to control the dimensions of the memory device 10, the dimensions of the SD device need to be reduced. However, by using the connection structure 230 in this implementation that is connected with one gate layer in each of a plurality of stack structures, even though the number of stack structures stacked in the first direction is further increased, the number of the SD devices isn't necessarily increased, so that the need for reducing dimensions of the SD device is avoided.

In this implementation, referring to FIGS. 6, 7 and 8, in the same reference plane 700 parallel to the second direction Y, at least two connection structures 230 have respective connection posts 233 of different sizes. For example, one cross section parallel to the second direction Y and the third direction Z may be taken from the memory device 10 and may serve as the reference plane 700. For ease of understanding, the memory device 10 will be explained with a plane parallel to the second direction Y and the third direction Z taken as a reference plane 700. At the same reference plane 700, among a plurality of connection structures 230, there are at least two ones having their respective connection posts 233 of different sizes. For example, one connection structure 230 has a connection post 233 with a size larger than that of the connection post 233 of another connection structure 230. It is to be noted that a size of a connection post 233 refers to the largest width of the connection post 233 in the reference plane 700. In an example, when the shape of the connection post 233 is circular in the reference plane 700, the size of the connection post 233 is the diameter of the connection post 233 in the reference plane 700.

With the first stack structure 210 taken as an example, the first stack structure 210 includes a plurality of first gate layers 211, and first connection layers 231 of a plurality of connection structures 230 are connected with the plurality of first gate layers 211 in one-to-one correspondence. Due to different positions of the first gate layers 211, the first connection layers 231 of different connection structures 230 are placed in different positions. Due to different positions of the first connection layers 231 of the plurality of connection structures 230, the connection posts 233 of the individual connection structures 230 are formed in different environments, causing at least two connection structures 230 to have their respective connection posts 233 of different sizes in the same reference plane 700 parallel to the second direction Y.

Moreover, a plurality of connection structures 230 may also be formed in the same fabrication operation, which is advantageous for the simplification of the fabrication process and saving the fabrication cost.

In some implementations, as shown in FIGS. 6 and 7, the memory device 10 further includes a channel structure 410 extending through the first stack structure 210 and the second stack structure 220 in the first direction X. In the reference plane 700, the size of the connection post 233 is larger than the size of the channel structure 410. It is to be noted that the size of the connection post 233 refers to the largest width of the connection post 233 in the reference plane 700 and the size of the channel structure 410 refers to the largest width of the channel structure 410 in the reference plane 700. In an example, when the shape of the connection post 233 is circular in the reference plane 700, the size of the connection post 233 is the diameter of the connection post 233 in the reference plane 700; and when the shape of the channel structure 410 is circular in the reference plane 700, the size of the channel structure 410 is the diameter of the channel structure 410 in the reference plane 700. Furthermore, the size of the connection post 233 is larger than the size of the channel structure 410, which is based on a premise that the connection post 233 and the channel structure 410 are in the same reference plane 700.

In the present implementation, since the channel structure 410 extends through the first stack structure 210 and the second stack structure 220 in the first direction X, while the connection structure 230 is located at a side of the first stack structure 210 and the second stack structure 220 in the second direction Y, it can be seen that the channel structure 410 and the connection structure 230 are formed in different environments, leading to the size of the connection post 233 larger than that of the channel structure 410 in the same reference plane 700.

In some implementations, as shown in FIGS. 6, the first stack structure 210 may include a first stack substructure 2101 and a second stack substructure 2102 stacked in the first direction X. It is to be noted that the first stack structure 210 may include, but not limited to, 2 stack substructures, 4 stack substructures, 8 stack substructures or the like to improve the storage capacity of the memory device 10. Furthermore, the first stack substructure 2101 and the second stack substructure 2102 are stacked in the first direction X to facilitate the improvement of the memory density of the memory device 10. The present implementation will be explained with an example, in which the first stack structure 210 includes 2 stack substructures.

The channel structure 410 includes a first channel structure 2103 and a second channel structure 2104 that are stacked in the first direction X, extend through the first stack substructure 2101 and the second stack substructure 2102 respectively and are connected with each other. In the present implementation, the first connection layers 231 of a plurality of connection structures 230 are connected with the first gate layers 211 in the first stack substructure 2101 in one-to-one-to-one correspondence, and the first connection layers 231 of a plurality of connection structures 230 are connected with the first gate layers 211 in the second stack substructure 2102 in one-to-one-to-one correspondence. In a similar way, the first stack structure 210 may include further stack structures stacked in the first direction X, which is advantageous for the improvement in the storage capacity of the memory device 10.

In an example, the second stack structure 220 may include a plurality of stack structures stacked in the first direction X, for example, a third stack substructure 2201 and a fourth stack substructure 2202 stacked in the first direction X. Correspondingly, the channel structure 410 may include a third channel structure 2203 and a fourth channel structure 2204 stacked in the first direction X, wherein the third channel structure 2203 extends through the third stack substructure 2201 and the fourth channel structure 2204 extends through the fourth stack substructure 2202; the third channel structure 2203 is connected with the fourth channel structure 2204; and the second channel structure 2104 is connected with the third channel structure 2203. By disposing and stacking further stack structures in the first direction X, the length of the channel structure 410 in the first direction X is increased, which is advantageous for improving the storage capacity of the memory device 10.

In some implementations, as shown in FIG. 6, the memory device 10 further includes a third stack structure 240 and a fourth stack structure 250 that are stacked in the first direction X and located on a side of the first stack structure 210 and the second stack structure 220 in the second direction Y, for example, both in the second region 102. A dielectric layer of a relatively larger thickness may be disposed between the third stack structure 240 and the fourth stack structure 250 to distinguish them from each other.

A connection post 233 extends through the third stack structure 240 and the fourth stack structure 250 in the first direction X. Here, the third stack structure 240 includes a plurality of third dielectric layers 241 and a plurality of fourth dielectric layers 242 stacked alternately in the first direction X. For example, the third dielectric layers 241 and the fourth dielectric layers 242 are stacked alternately in the first direction X to form a plurality of third dielectric layers 241 spaced from each other and a plurality of fourth dielectric layers 242 spaced from each other. At least one third dielectric layer 241 is connected with at least one first connection layer 231, and the first connection layer 231 connected with the third dielectric layer 241 may be connected with one first gate layer 211.

The fourth stack structure 250 includes a plurality of fifth dielectric layers 251 and a plurality of sixth dielectric layers 252 stacked alternately in the first direction X. For example, the fifth dielectric layers 251 and the sixth dielectric layers 252 are stacked alternately in the first direction X to form a plurality of fifth dielectric layers 251 spaced from each other and a plurality of sixth dielectric layers 252 spaced from each other. At least one fifth dielectric layer 251 is connected with at least one second connection layer 232, and the second connection layer 232 connected with the fifth dielectric layer 251 may be connected with one second gate layer 221.

In an example, the third dielectric layer 241 may be connected with the first gate layer 211, and the fourth dielectric layer 242 may be connected with the first dielectric layer 212. Moreover, the fourth dielectric layers 242 may include the same material as the first dielectric layers 212 and furthermore be located at the same layer as the first dielectric layer 212. Disposing at the same layer means that a plurality of patterns are located at the same pattern layer, which is a film layer formed through a one-time patterning process. The patterning process refers to a process capable of forming at least one pattern of a certain shape. For example, a thin film is formed on a base substrate through any of various film forming processes such as deposition, coating, sputtering and the like, and then patterned to form a film layer including at least one pattern, which is called as a pattern layer. The patterning includes coating of a photoresist, exposure, developing, etching and stripping of the photoresist. In the present implementation, a plurality of patterns belonging to the same pattern layer have a position relationship called as disposing at the same layer.

In an example, the fifth dielectric layer 251 may be connected with the second gate layer 221, and the sixth dielectric layer 252 may be connected with the second dielectric layer 222. Moreover, the sixth dielectric layer 252 may include the same material as the second dielectric layer 222 and furthermore be located at the same layer as the second dielectric layer 222. For example, the first dielectric layer 212, the second dielectric layer 222, the fourth dielectric layer 242 and the sixth dielectric layer 252 each include oxide, while the third dielectric layer 241 and the fifth dielectric layer 251 each include nitride.

Referring to FIG. 1, during formation of the contacts G-CNT, since each contact G-CNT needs to extend to a different gate layer, the process of forming the contacts G-CNT faces more difficulty.

In the present implementation, however, connection posts 233 of a plurality of connection structures 230 each extend through the third stack structure 240 and the fourth stack structure 250. In comparison with the implementation, in which the contacts G-CNT extend to different gate layers respectively, the present implementation facilitates the reduction of the process difficulty of fabricating the memory device 10 and the improvement of the fabrication efficiency of the memory device 10.

In some implementations, as shown in FIGS. 6, the connection post 233 includes a first connection post 2331 and a second connection post 2332 stacked in the first direction X. The first connection post 2331 extends through the third stack structure 240 and the second connection post 2332 extends through the fourth stack structure 250. The first connection post 2331 and the second connection post 2332 may be configured as one piece. In the second direction Y, a size of an end of the first connection post 2331 proximate to the second connection post 2332 is larger than a size of an end of the second connection post 2332 proximate to the first connection post 2331. Here, the size of the end of the first connection post 2331 proximate to the second connection post 2332 may be understood as the largest width of the surface of the first connection post 2331 in a Y-Z plane, through which the first connection post 2331 is in contact with the second connection post 2332; and the size of the end of the second connection post 2332 proximate to the first connection post 2331 may be understood as the largest width of the surface of the second connection post 2332 in a Y-Z plane, through which the second connection post 2332 is in contact with the first connection post 2331.

In an example, the first connection post 2331 has a first surface a and a second surface b that are opposite to each other in the first direction X, and the second surface b is closer to the second connection post 2332 than the first surface a; and the second connection post 2332 has a third surface c and a fourth surface d that are opposite to each other in the first direction X, and the third surface c is closer to the first connection post 2331 than the fourth surface d. Here, the largest width of the second surface b is larger than that of the third surface c.

For example, each of the first connection post 2331 and the second connection post 2332 may be a circular truncated cone structure. The diameter of the end of the first connection post 2331 proximate to the second connection post 2332 is larger than the diameter of the end of the second connection post 2332 proximate to the first connection post 2331.

In the present implementation, in the plane, in which the first connection post 2331 and the second connection post 2332 are in contact with each other, and in the second direction Y, the first connection post 2331 may fully overlap the second connection post 2332, i.e., the perimeter of the third surface c may be located within the perimeter of the second surface b; or the first connection post 2331 may partially overlap the second connection post 2332, i.e., a part of the perimeter of the third surface c may be located outside the perimeter of the second surface b.

With the configuration above, the process window for enabling the contact and connection between the second connection post 2332 and the first connection post 2331 is advantageously enlarged, which facilitates the connection between the second connection post 2332 and the first connection post 2331 and improves the reliability of the connection therebetween, and thus improves the memory reliability of the memory device 10.

In some implementations, as shown in FIG. 6, in the second direction Y, a size of an end of the first connection post 2331 proximate to the second connection post 2332 is larger than a size of an end of the first connection post 2331 away from the second connection post 2332. For example, the largest width of the second surface b is larger than that of the first surface a.

Furthermore, in the second direction Y, a size of an end of the second connection post 2332 away from the first connection post 2331 is larger than a size of an end of the second connection post 2332 proximate to the first connection post 2331. For example, the largest width of the fourth surface d is larger than that of the third surface c.

With the configuration above, the process window for enabling the contact and connection between the second connection post 2332 and the first connection post 2331 is advantageously enlarged, which facilitates the connection between the second connection post 2332 and the first connection post 2331 and improves the reliability of the connection therebetween, and thus improves the memory reliability of the memory device 10.

In some implementations, as shown in FIG. 6, the memory device 10 further includes a plurality of first isolation layers 260 and a plurality of second isolation layers 270. One first isolation layer 260 extends partially through the third stack structure 240 to one first connection layer 231, and is disposed to surround one connection post 233. First isolation layers 260 are disposed in one-to-one correspondence with first connection layers 231. For example, the first isolation layer 260 may cover a surface of a perimeter of the corresponding first connection post 2331 to isolate the first connection post 2331 and prevent a leakage current from occurring between the first connection post 2331 and other conductive structures, which is advantageous for improving storage reliability of the memory device 10.

One second isolation layer 270 extends partially through the fourth stack structure 250 to one second connection layer 232 and is disposed to surround one connection post 233. Second isolation layers 270 are disposed in one-to-one correspondence with second connection layers 232. For example, the second isolation layer 270 may cover a surface of a perimeter of the corresponding second connection post 2332 to isolate the second connection post 2332 and prevent a leakage current from occurring between the second connection post 2332 and other conductive structures, which is advantageous for improving storage reliability of the memory device 10.

Furthermore, the third stack structure 240 adjoins the first stack structure 210 in the second direction Y, and the first stack structure 210 may include a first stack substructure and a second stack substructure, so that the first connection post 2331 may correspond to the first stack substructure 2101 and the second stack substructure 2102, i.e., one first connection post 2331 and one first isolation layer 260 may correspond to two stack structures. Compared to the scheme, in which one first connection post 2331 and one first isolation layer 260 correspond to one stack structure, this scheme may save one first isolation layer 260, which is advantageous for the simplification of the fabrication process and reducing the fabrication cost.

In some other implementations, as shown in FIG. 6, a size of an end of the first isolation layer 260 away from the first connection layer 231 and in the second direction Y is larger than a size of an end of the first isolation layer 260 proximate to the first connection layer 231 and in the second direction Y. In the second direction Y, the first isolation layer 260 has a certain thickness and the thickness an end of the first isolation layer 260 proximate to the second connection post 2332 is larger than the thickness of an end of the first isolation layer 260 proximate to the first connection layer 231. As such, the effect of isolating the end of the first connection post 2331 proximate to the second connection post 2332 can be further advantageously improved.

With continued reference to FIG. 6, in the second direction Y, the second isolation layer 270 has a certain thickness and the thickness of an end of the second isolation layer 270 away from the first connection post 2331 is larger than the thickness of an end of the second isolation layer 270 proximate to the first connection post 2331. As such, the effect of isolating the end of the second connection post 2332 away from the first connection post 2331 by the second isolation layer 270 can be further advantageously improved.

In an example, the first isolation layer 260 and the second isolation layer 270 may include, for example, one of oxide, nitride, and an insulating material with a high dielectric constant, or any combination thereof, or may include any other suitable insulating material. The present disclosure is explained with an example, in which the first isolation layer 260 and the second isolation layer 270 are both include silicon oxide.

As shown in FIG. 6, the connection structure 230 needs to extend through the second isolation layer 270, the fourth stack structure 250, the first isolation layer 260 and the third stack structure 240. With the first isolation layer 260 and the third stack structure 240 taken as an example, in some implementations, the first isolation layer 260 is a layer of silicon oxide and the third stack structure 240 is a deck structure of silicon oxide layers and silicon nitride layers stacked alternately, so that the etching rate of the first isolation layer 260 is different from that of the third stack structure 240. The relationship in amplitude between the etching rates of the first isolation layer 260 and the third stack structure 240 has two instances. In the first one, the etching rate of the first isolation layer 260 is smaller than that of the third stack structure 240, and in the second one, the etching rate of the first isolation layer 260 is larger than that of the third stack structure 240. The structural characteristics of the connection structure 230 in the two instances above will be explained in connection with FIGS. 6, 7 and 8.

It is to be noted that, for case of understanding, the following implementations will be explained with an example, in which the second isolation layer 270 has the same largest size in the first direction X and the same constituent materials as the first isolation layer 260 in the same connection structure 230, and the fourth stack structure 250 has the same constituent materials as the third stack structure 240.

In some implementations, when the etching rate of the first isolation layer 260 is smaller than that of the third stack structure 240, with reference to FIGS. 6 and 7, one of a plurality of connection structures 230 is a first connection structure 234 and another one of the plurality of connection structures 230 is a second connection structure 235. In the first direction X, the largest size of the first isolation layer 260 surrounding the first connection structure 234 is larger than the largest size of the first isolation layer 260 surrounding the second connection structure 235. In a reference plane 700 (one and the same reference plane 700 here), the size of the connection post 233 of the first connection structure 234 is larger than the size of the connection post 233 of the second connection structure 235.

It is to be noted that the largest size of the first isolation layer 260 in the first direction X may be understood as the largest thickness of the first isolation layer 260 in FIG. 6. In a reference plane 700, the size of a connection post 233 may be understood as the largest width of the connection post 233 in the reference plane 700, and when the connection post 233 is a cylindrical structure, the size of the connection post 233 in the reference plane 700 is the diameter of the cross section of the connection post 233 taken by the reference plane 700.

In the present implementation, the first connection structure 234 and the second connection structure 235 may have the same length in the first direction X. The largest thickness of the first isolation layer 260 surrounding the first connection structure 234 is larger than the largest thickness of the first isolation layer 260 surrounding the second connection structure 235, so that the thickness of third stack structure 240, through which the first connection structure 234 needs to extend, is smaller than the thickness of the third stack structure 240, through which the second connection structure 235 needs to extend. However, the etching rate of the first isolation layer 260 is smaller than that of the third stack structure 240, so that for the first connection structure 234 and the second connection structure 235 formed through the same fabrication process, in a reference plane 700 the largest width of the connection post 233 of the first connection structure 234 is larger than the largest width of the connection post 233 of the second connection structure 235.

Moreover, when the etching rate of the first isolation layer 260 is smaller than the etching rate of the third stack structure 240, among a plurality of first isolation layers 260, the thicker a first isolation layer 260 is, the larger the width in the reference plane 700 of the connection post 233 of the connection structure 230 surrounded by the first isolation layer 260 is; and conversely, the thinner a first isolation layer 260 is, the smaller the width in the reference plane 700 of the connection post 233 of the connection structure 230 surrounded by the first isolation layer 260 is.

Furthermore, during fabrication of the memory device 10, the first connection structure 234 and the second connection structure 235 are formed in the same operations, simplifying the process operations and advantageously improving the fabrication efficiency of the memory device 10.

In some other implementations, when the etching rate of the first isolation layer 260 is larger than that of the third stack structure 240, with reference to FIGS. 6 and 8, one of a plurality of connection structures 230 is a first connection structure 234 and another one of the plurality of connection structures 230 is a second connection structure 235. In the first direction X, the largest size of the first isolation layer 260 surrounding the first connection structure 234 is larger than the largest size of the first isolation layer 260 surrounding the second connection structure 235. In a reference plane 700 (one and the same reference plane 700 here), the size of the connection post 233 of the first connection structure 234 is smaller than the size of the connection post 233 of the second connection structure 235.

It is to be noted that the largest size of the first isolation layer 260 in the first direction X may be understood as the largest thickness of the first isolation layer 260 in FIG. 6. In a reference plane 700, the size of the connection post 233 may be understood as the largest width of the connection post 233 in the reference plane 700, and when the connection post 233 is a cylindrical structure, the size of the connection post 233 in the reference plane 700 is the diameter of the cross section of the connection post 233 taken by the reference plane 700.

In the present implementation, the first connection structure 234 and the second connection structure 235 may have the same length in the first direction X. The largest thickness of the first isolation layer 260 surrounding the first connection structure 234 is larger than the largest thickness of the first isolation layer 260 surrounding the second connection structure 235, so that the thickness of third stack structure 240, through which the first connection structure 234 needs to extend, is smaller than the thickness of the third stack structure 240, through which the second connection structure 235 needs to extend. However, the etching rate of the first isolation layer 260 is larger than that of the third stack structure 240, so that for the first connection structure 234 and the second connection structure 235 formed through the same fabrication process, in a reference plane 700 the largest width of the connection post 233 of the first connection structure 234 is smaller than the largest width of the connection post 233 of the second connection structure 235.

Moreover, when the etching rate of the first isolation layer 260 is larger than the etching rate of the third stack structure 240, among a plurality of first isolation layers 260, the thicker a first isolation layer 260 is, the smaller the width in the reference plane 700 of the connection post 233 of the connection structure 230 surrounded by the first isolation layer 260 is; and conversely, the thinner a first isolation layer 260 is, the larger the width in the reference plane 700 of the connection post 233 of the connection structure 230 surrounded by the first isolation layer 260 is.

Furthermore, during fabrication of the memory device 10, the first connection structure 234 and the second connection structure 235 are formed in the same operations, simplifying the process operations and advantageously improving the fabrication efficiency of the memory device 10.

In some implementations, with reference to FIGS. 6, 7 and 8, in a reference plane 700 the size of the first isolation layer 260 surrounding the first connection structure 234 is larger than the size of the first isolation layer 260 surrounding the second connection structure 235. Here, the size of the first isolation layer 260 in a reference plane 700 may be understood as the largest width of the first isolation layer 260 in the reference plane 700. Then, in the first direction X, the largest thickness of the first isolation layer 260 surrounding the first connection structure 234 is larger than the largest thickness of the first isolation layer 260 surrounding the second connection structure 235, and in the reference plane 700 the largest width of the first isolation layer 260 surrounding the first connection structure 234 is larger than the largest width of the first isolation layer 260 surrounding the second connection structure 235.

The configuration above is beneficial for a plurality of first isolation layers 260 to isolate respective connection structures 230 and a leakage current is prevented from occurring between the plurality of connection structures 230 and other conductive structures, which is advantageous for improving storage reliability of the memory device 10.

Moreover, it can be understood that for a plurality of first isolation layers 260 formed in the same fabrication process, in the same reference plane 700, the wider a first isolation layer 260 is, the larger the thickness of the first isolation layer 260 in the first direction X is.

In some implementations, with reference to FIG. 7, one of the plurality of connection structures 230 is a third connection structure 236, and the first connection structure 234, the third connection structure 236 and the second connection structure 235 are arranged in this order in a reference direction. The reference direction crosses the first direction X and may be, for example, the second direction Y. In a reference plane 700, the size of the connection post 233 of the first connection structure 234 is larger than the size of the connection post 233 of the third connection structure 236 and the size of the connection post 233 of the second connection structure 235 is larger than the size of the connection post 233 of the third connection structure 236.

It is to be noted that the size of the connection post 233 in the reference plane 700 can be understood as the largest width of the connection post 233 in the reference plane 700. Then in the reference plane 700, the largest width of the connection post 233 of the first connection structure 234 is larger than the largest width of the connection post 233 of the third connection structure 236 and the largest width of the connection post 233 of the second connection structure 235 is larger than the largest width of the connection post 233 of the third connection structure 236.

In order to prevent a leakage current from occurring between adjacent connection structures 230, a spacing is needed therebetween.

In the present implementation, by disposing the third connection structure 236 having a connection post 233 with the smallest width between the first connection structure 234 and the second connection structure 235 and due to the largest width of the connection post 233 of the first connection structure 234 larger than that of the connection post 233 of the third connection structure 236 in the reference plane 700 and the largest width of the connection post 233 of the second connection structure 235 larger than that of the connection post 233 of the third connection structure 236 in the reference plane 700, the spacing between the third connection structure 236 and the first connection structure 234 may be smaller than that between two adjacent first connection structures 234. For the same reasons, the spacing between the third connection structure 236 and the second connection structure 235 may be smaller than the spacing between two adjacent second connection structures 235 and smaller than the spacing between the second connection structure 235 and the first connection structure 234. Therefore, the configuration above is advantageous to improve the density of a plurality of connection structures 230 in the reference direction, and improve the storage density of the memory device 10, and is also advantageous for the memory device 10 to develop towards a larger capacity and a smaller volume.

In some other implementations, with reference to FIG. 8, one of the plurality of connection structures 230 is a third connection structure 236 and the first connection structure 234, the third connection structure 236 and the second connection structure 235 are arranged in this order in a reference direction. The reference direction crosses the first direction X and may be, for example, the second direction Y. In a reference plane 700, the size of the connection post 233 of the first connection structure 234 is smaller than the size of the connection post 233 of the third connection structure 236 and the size of the connection post 233 of the second connection structure 235 is smaller than the size of the connection post 233 of the third connection structure 236.

It is to be noted that the size of the connection post 233 in the reference plane 700 can be understood as the largest width of the connection post 233 in the reference plane 700. Then in the reference plane 700, the largest width of the connection post 233 of the first connection structure 234 is smaller than the largest width of the connection post 233 of the third connection structure 236 and the largest width of the connection post 233 of the second connection structure 235 is smaller than largest width size of the connection post 233 of the third connection structure 236.

In order to prevent a leakage current from occurring between adjacent connection structures 230, a spacing is needed therebetween.

In the present implementation, by disposing the third connection structure 236 having a connection post 233 with the largest width between the first connection structure 234 and the second connection structure 235 and due to the largest width of the connection post 233 of the first connection structure 234 smaller than that of the connection post 233 of the third connection structure 236 in the reference plane 700 and the largest width of the connection post 233 of the second connection structure 235 smaller than that of the connection post 233 of the third connection structure 236 in the reference plane 700, the spacing between the third connection structure 236 and the first connection structure 234 may be smaller than that between two adjacent third connection structures 236. For the same reasons, the spacing between the third connection structure 236 and the second connection structure 235 may be smaller than the spacing between two adjacent third connection structures 236. Therefore, the configuration above is advantageous to improve the density of a plurality of connection structures 230 in the reference direction, and improve the storage density of the memory device 10 and is also advantageous for the memory device 10 to develop towards a larger capacity and a smaller volume.

In some implementations, with reference to FIG. 6, the first connection layer 231 includes a first sublayer 2311 and a second sublayer 2312 stacked in the first direction X with the first sublayer 2311 located between the first isolation layer 260 and the second sublayer 2312 and the first isolation layer 260 surrounding the first sublayer 2311. Both the first sublayer 2311 and the second sublayer 2312 are disposed to surround and contact the corresponding first connection post 2331. The first sublayer 2311 and the second sublayer 2312 are stacked in the first direction X and in contact with each other and are both electrically connected with the first connection post 2331. The second sublayer 2312 is also connected with a first gate layer 211. The first connection layer 231 is connected with the first connection post 2331 and the first gate layer 211 via the first sublayer 2311 and the second sublayer 2312, increasing the area of contact between the first connection layer 231 and the first connection post 2331, which is advantageous for improving the reliability of electrical connection between the first connection layer 231 and the first connection post 2331.

Furthermore, a first isolation layer 260 may surround the first sublayer 2311 to prevent leakage currents from occurring between the first sublayer 2311 and other conductive structures, which is advantageous for improving storage reliability of the memory device 10.

In some implementations, as shown in FIG. 6, the first isolation layer 260 includes a first isolation sublayer 261, a second isolation sublayer 262 and a third isolation sublayer 263. The first isolation sublayer 261 surrounds the connection post 233. The second isolation sublayer 262 is located between the first isolation sublayer 261 and the connection post 233 and surrounds the connection post 233. The third isolation sublayer 263 is located between the second isolation sublayer 262 and the connection post 233 and surrounds the connection post 233.

In an example, the first isolation sublayer 261, the second isolation sublayer 262 and the third isolation sublayer 263 may include an insulating material. For example, the insulating material may be any one of silicon oxide, silicon nitride, and an insulating material with a high dielectric constant, or any combination thereof, or may be any other insulating material. The first isolation sublayer 261, the second isolation sublayer 262 and the third isolation sublayer 263 may include the same material or different materials and the present disclosure is not limited in this respect.

By using the configuration above, the first isolation sublayer 261, the second isolation sublayer 262 and the third isolation sublayer 263 together are used to isolate the first connection post 2331 on a side of the first connection layer 231 proximate to the second connection layer 232, which facilitates enhancement of the effect of isolating the first connection post 2331 by the first isolation layer 260, and thus prevents leakage currents from occurring between the first sublayer 2311 and other conductive structures, which is advantageous for improving storage reliability of the memory device 10.

In some implementations, as shown in FIG. 6, the first connection structure 234 further includes a third isolation layer 280 and a fourth isolation layer 290. Here, the third isolation layer 280 is located on a side of the first connection layer 231 away from the first isolation layer 260, is in contact with the first connection post 2331, and surrounds the first connection post 2331. It can be understood that the first isolation layer 260 is located above the first connection layer 231 and surrounds the first connection post 2331 to isolate a part of the first connection post 2331 above the first connection layer 231; and the third isolation layer 280 is located below the first connection layer 231 and surrounds the first connection post 2331 to isolate a part of the first connection post 2331 below the first connection layer 231. Both the first isolation layer 260 and the third isolation layer 280 are in contact with the first connection post 2331.

The fourth isolation layer 290 is located on a side of the second connection layer 232 away from the second isolation layer 270, is in contact with the second connection post 2332, and surrounds the second connection post 2332. It can be understood that the second isolation layer 270 is located above the second connection layer 232 and surrounds the second connection post 2332 to isolate a part of the second connection post 2332 above the second connection layer 232; and the fourth isolation layer 290 is located below the second connection layer 232 and surrounds the second connection post 2332 to isolate a part of the second connection post 2332 below the second connection layer 232. Both the second isolation layer 270 and the fourth isolation layer 290 are in contact with the second connection post 2332.

The third isolation layer 280 is configured to facilitate isolation of the first connection post 2331, prevent leakage currents from occurring between the first connection post 2331 and other conductive structures and facilitate improvement of storage reliability of the memory device 10. The fourth isolation layer 290 is configured to facilitate isolation of the second connection post 2332, prevent leakage currents from occurring between the second connection post 2332 and other conductive structures and facilitate improvement of storage reliability of the memory device 10.

In some implementations, the memory device 10 further includes a first select gate 2111, a second select gate 2112, a third select gate 2211, a fourth select gate 2212 and a fourth connection structure 237. Here, the first select gate 2111 is located on a side of the first stack structure 210 away from the second stack structure 220. The second select gate 2112 is located on a side of the first stack structure 210 proximate to the second stack structure 220. The third select gate 2211 is located on a side of the second stack structure 220 proximate to the first stack structure 210. The fourth select gate 2212 is located on a side of the second stack structure 220 away from the first stack structure 210. One of the first select gate 2111, the second select gate 2112, the third select gate 2211 and the fourth select gate 2212 is connected with the fourth connection structure 237.

The fourth connection structure 237 is located on a side of the first stack structure 210 and the second stack structure 220 in the second direction Y. For example, both the first stack structure 210 and the second stack structure 220 may be located in the first region 101, while the fourth connection structure 237 may be located in the second region 102. The fourth connection structure 237 may be connected with the first select gate 2111; or the fourth connection structure 237 is connected with the second select gate 2112; or the fourth connection structure 237 is connected with the third select gate 2211; or the fourth connection structure 237 is connected with the fourth select gate 2212.

By the configuration above, in the memory device 10, either the channel structure in the first stack structure 210 or the channel structure in the second stack structure 220 may be selected to be turned on through the fourth connection structure 237, and then storage nodes in the first stack structure 210 or the second stack structure 220 may be selected to be read/written through other connection structures 230 and bit lines.

In an example, there may be a plurality of fourth connection structures 230, e.g., one fourth connection structure 237 connected with the first select gate 2111, one fourth connection structure 237 connected with the second select gate 2112, one fourth connection structure 237 connected with the third select gate 2211, and one fourth connection structure 237 connected with the fourth select gate 2212. As such, a plurality of fourth connection structures 230 are configured, and when one of them is in poor connection, the first stack structure 210 and the second stack structure 220 can be selected through any other fourth connection structure 237, which facilitates improvement of storage reliability of the memory device 10.

In some implementations, as shown in FIGS. 5-6, the memory device 10 further includes a first bit line BL-1 and a second bit line BL-2. The first bit line BL-1 is located on a side of the first select gate 2111 away from the first stack structure 210, while the second bit line BL-2 is located on a side of the fourth select gate 2212 away from the first stack structure 210. The extending direction of the first bit line BL-1 and the second bit line BL-2 crosses the first direction X. The extending direction of the first bit line BL-1 may be parallel to the extending direction of the second bit line BL-2.

It is to be noted that when a plurality of stack structures are further stacked in the memory device 10, the first bit line BL-1 and the second bit line BL-2 are located on two opposed sides of all the stack structures in the first direction X respectively, and active layers are disposed between adjacent stack structures.

In the present implementation, an active layer (e.g., deposited silicon) may be formed between the first stack structure 210 and the second stack structure 220, and may have a side in contact with a first dielectric layer 212 in the first stack structure 210 and the other side in contact with a second dielectric layer 222 in the second stack structure 220. The channel structure in the first stack structure 210 may extend through the first stack structure 210 and be connected with the active layer, and the channel structure in the second stack structure 220 may extend through the second stack structure 220 and be connected with the active layer. The channel structure in the first stack structure 210 may be in communication with the channel structure in the second stack structure 220.

By the configuration above, the first bit line BL-1, the channel structure in the first stack structure 210, the channel structure in the second stack structure 220 and the second bit line BL-2 are all in communication with each other, so that the channel structures in the first stack structure 210 and the second stack structure 220 may be driven by the first bit line BL-1 and the second bit line BL-2.

In some implementations, the memory device 10 further includes a third bit line BL-3. The third bit line BL-3 is located between the second select gate 2112 and the third select gate 2211, and has an extending direction crossing the first direction X. The third bit line BL-3 may extend in a Y-Z plane. For example, the extending direction of the third bit line BL-3 may be parallel to the third direction Z.

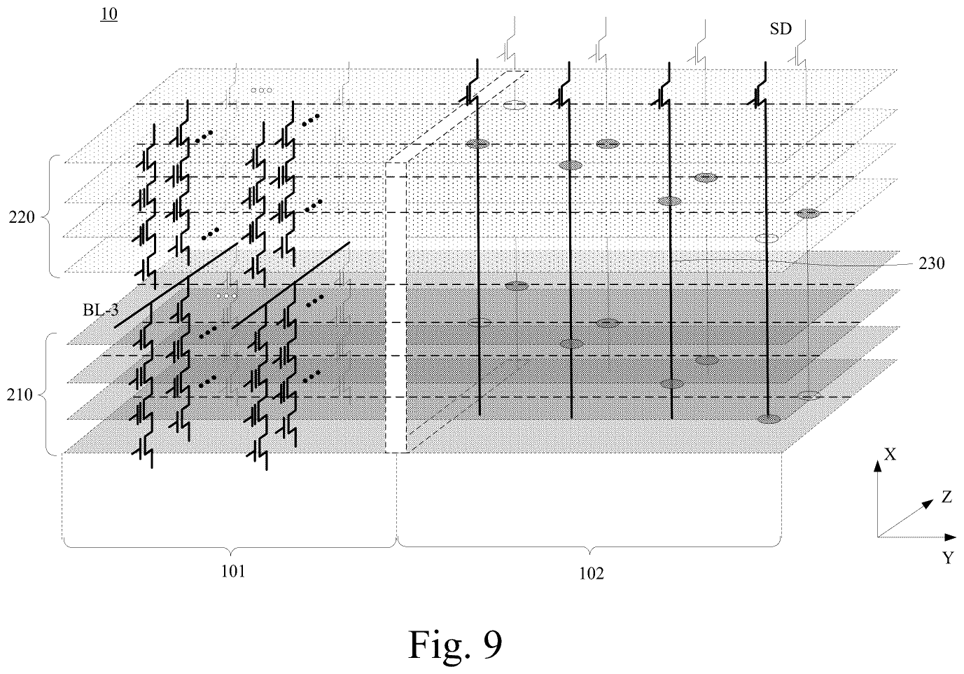

As shown in FIGS. 6 and 9, the third bit line BL-3 is located between the first stack structure 210 and the second stack structure 220, and connected with both the channel structure in the first stack structure 210 and the channel structure 410 in the second stack structure 220. There may be a plurality of third bit lines BL-3 that are arranged to be spaced from each other in the second direction Y. By the configuration above, the third bit line BL-3 is located between the first stack structure 210 and the second stack structure 220 and may drive the channel structure in the first stack structure 210 upward and meanwhile drive the channel structure in the second stack structure 220 downward. In some other implementations, a third bit line BL-3 is located at the top-most end of a plurality of stack structures (in this implementation, the end of the second stack structure 220 away from the first stack structure 210), and due to the resistance in the channel structures, the current in a channel structure far away from the third bit line BL-3 is relatively weak. Compared to the scheme, in which the third bit line BL-3 is located at the top-most end of a plurality of stack structures, the present implementation, in which the third bit line BL-3 is located between the first stack structure 210 and the second stack structure 220, facilitates improvement of current intensities in the channel structures and mitigates the problem of relatively weak current intensities in the channel structures far away from the third bit line BL-3.

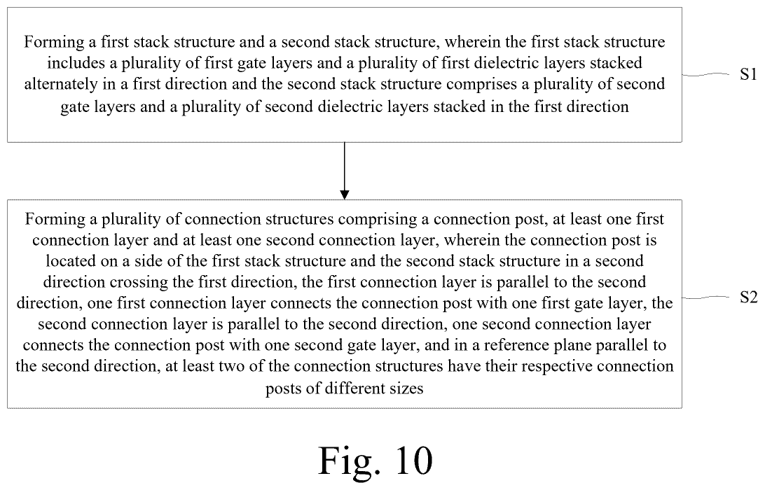

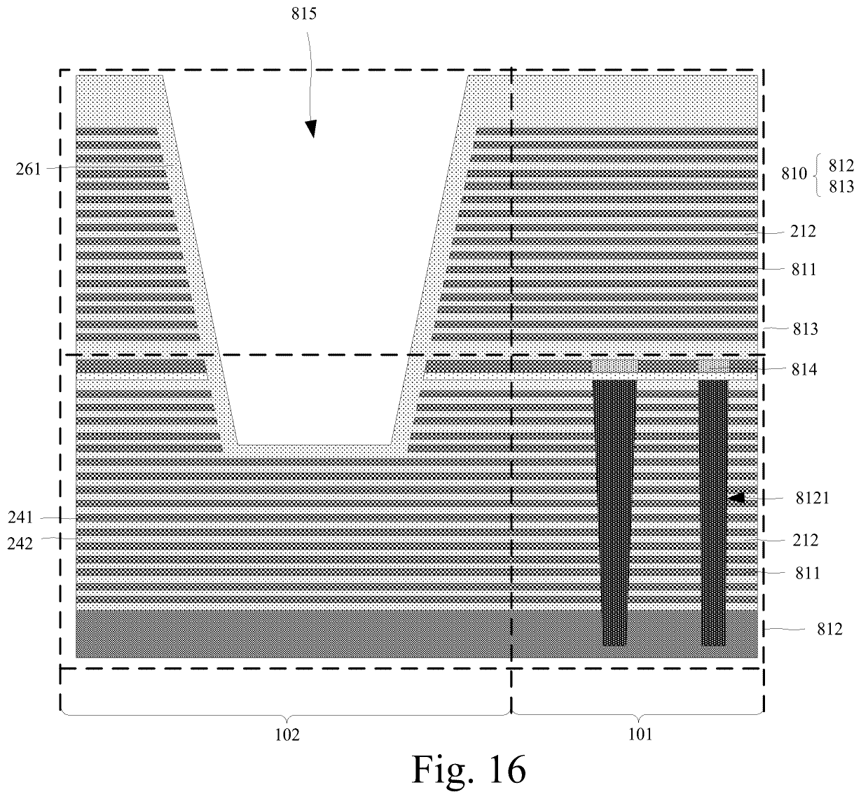

Some implementations of the present disclosure further provide a method of fabricating a memory device 10, which will be explained below in connection with FIGS. 10 to 24.

FIG. 10 is a flow chart of a method of fabricating a memory device in accordance with some implementations. As shown in FIG. 10, the method of fabricating a memory device provided in some implementations of the present disclosure includes operations S1 and S2.

In operation S1, a first stack structure and a second stack structure are formed, wherein the first stack structure includes a plurality of first gate layers and a plurality of first dielectric layers stacked alternately in a first direction, and the second stack structure includes a plurality of second gate layers and a plurality of second dielectric layers stacked in the first direction; and the second stack structure and the first stack structure are stacked in the first direction.

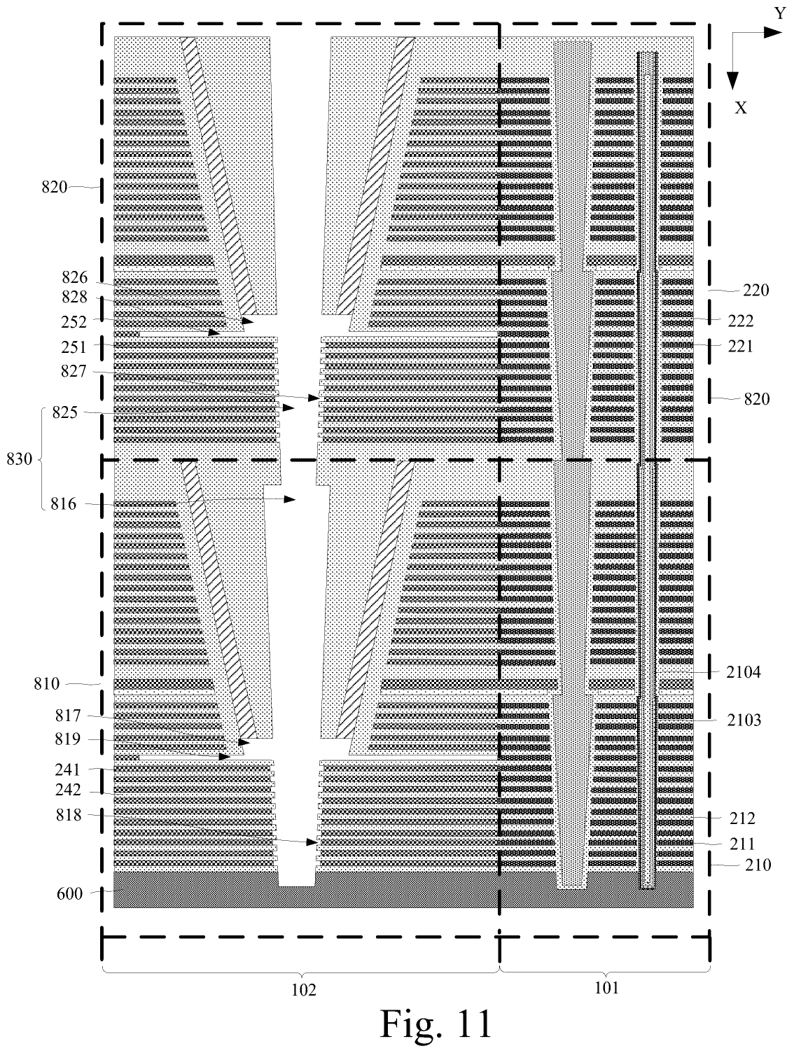

In some implementations, with reference to FIG. 11, forming the first stack structure 210 and the second stack structure 220 includes: forming a first deck structure 810 having a first region 101 including a plurality of first sacrificial layers 811 and a plurality of first dielectric layers 212 stacked alternately in the first direction X and a second region 102 that adjoins the first region 101 and is on a side of the first region 101 of the first deck structure 810 in a second direction Y crossing the first direction X.

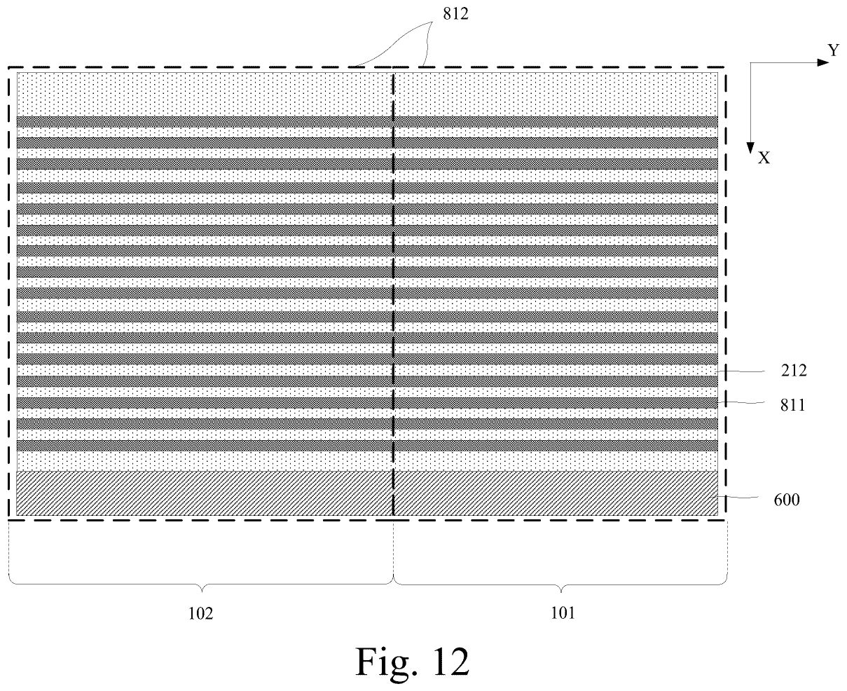

In the present operation, with reference to FIG. 12, the first dielectric layers 212 and the first sacrificial layers 811 may be formed alternately on a semiconductor layer 600 through a deposition process. The deposition process includes, but not limited to, one or more of physical vapor deposition (PVD), chemical vapor deposition (CVD) and atomic layer deposition (ALD) as thin film deposition processes.

Here, the semiconductor layer 600 may include silicon (e.g. single crystal silicon or polysilicon), silicon germanium (SiGe), gallium arsenide (GaAs), germanium (Ge), silicon on insulator (SOI) and/or any other suitable semiconductor material.

The first dielectric layers 212 may include an insulating material including any one of silicon oxide, silicon nitride, silicon oxynitride, and an insulating material with a high dielectric constant, or any combination thereof, or may include any other suitable insulating material.

The first sacrificial layers 811 may also include the above-mentioned insulating material, however since the first sacrificial layers 811 need to be removed during a subsequent fabrication operation, this material for the first sacrificial layers 811 needs to be different from that of the first dielectric layers 212, so that the first dielectric layers 212 are protected from being damaged when the first sacrificial layers 811 are removed. The present implementation will be explained with an example, in which the first dielectric layers 212 include silicon oxide and the first sacrificial layers 811 include silicon nitride.

In the present implementation, with reference to FIG. 12, forming the first deck structure 810 may include: forming a first deck substructure 812 having a first region 101 including a plurality of first sacrificial layers 811 and a plurality of first dielectric layers 212 stacked alternately in the first direction and a second region 102 that adjoins the first region 101 and is on a side of the first region 101 of the first deck substructure 812 in the second direction Y.

In the present operation, the first dielectric layers 212 and the first sacrificial layers 811 may be formed alternately on a semiconductor layer 600 through a deposition process to form the first deck substructure 812.

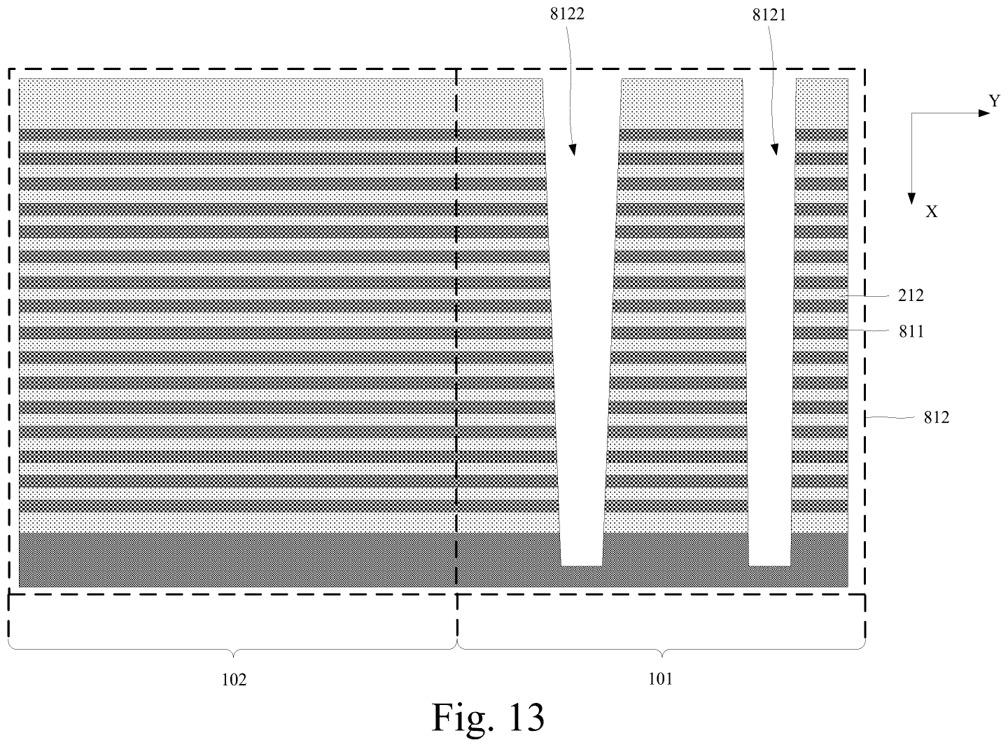

Referring to FIGS. 12 and 13, after formation of the first deck substructure 812, the method further includes: removing a part of the first deck substructure 812 to form a first channel hole 8121 and a first gate slit 8122 that both extend through the first region 101 of the first deck substructure 812 with the first gate slit 8122 located on a side of the first channel hole 8121.

In the present operation, the first channel hole 8121 and the first gate slit 8122 may be formed using any suitable fabrication processes. For example, a patterned photoresist layer may be formed on the first deck substructure 812. The patterned photoresist layer can expose a part of the first deck substructure 812, where the first channel hole 8121 and the first gate slit 8122 are to be formed. A suitable etching process may be performed to remove a part of the first deck substructure 812, where the first channel hole 8121 and the first gate slit 8122 are to be formed. For example, the etching process may include a dry etching process.

After formation of the first channel hole 8121 and the first gate slit 8122, the patterned photoresist layer on the first deck substructure 812 may be removed. For example, the surface of the first deck substructure 812 may be planarized using chemical mechanical polishing (CMP) to remove the patterned photoresist layer on the first deck substructure 812.

After removing the patterned photoresist layer on the first deck substructure 812, a sacrificial material, for example, carbon, may be deposited into the first channel hole 8121 and the first gate slit 8122 to facilitate formation of a second deck substructure 813 on the first deck substructure 812 during a subsequent fabrication operation.

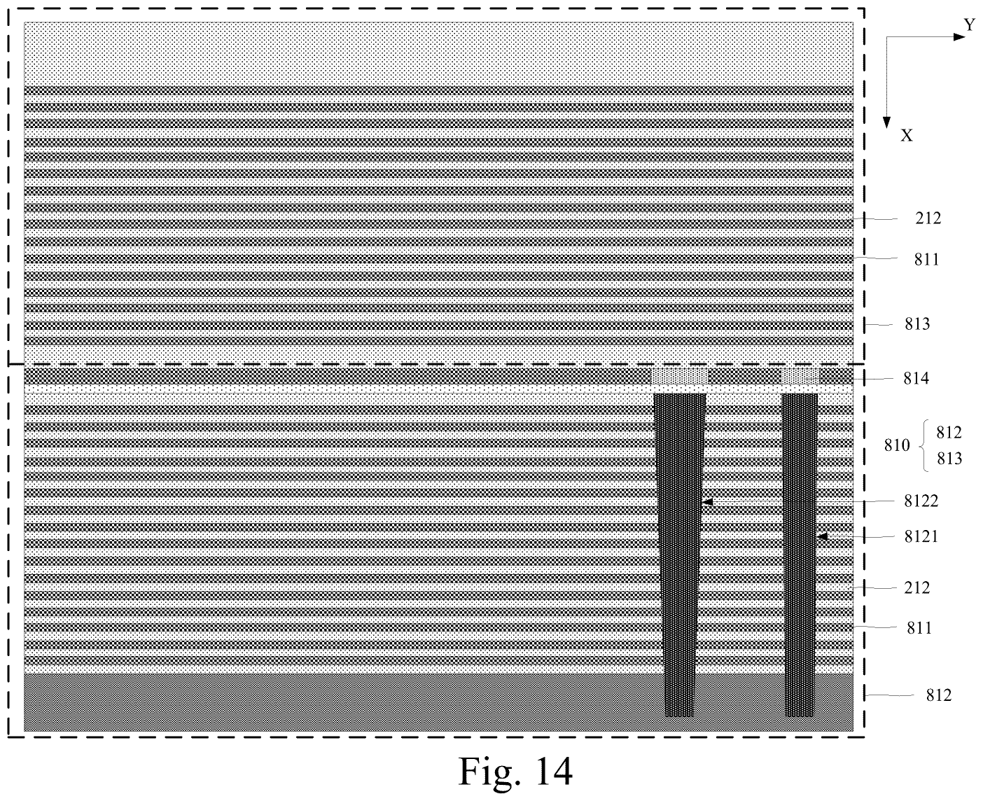

As shown in FIG. 14, after formation of the first deck substructure 812 and before formation of the second deck substructure 813, the method further includes: forming an etch stop layer 814 that is stacked with the first channel hole 8121 in the first direction X.

In the present operation, after the sacrificial material is filled into the first channel hole 8121 and the first gate slit 8122, the etch stop layer 814 may be formed above the first channel hole 8121 and the first gate slit 8122. The etch stop layer 814 may include a chemically inert material, for example, silicon nitride or silicon oxynitride. The etch stop layer 814 has relatively high chemical stability and etching resistance to resist corrosion by etching liquid, and thus acts as a protective layer over first channel hole 8121 and the first gate slit 8122, which can protect first channel hole 8121 and the first gate slit 8122 below the etch stop layer 814 from being corroded.

With continued reference to FIG. 14, the second deck substructure 813 is formed on a side of the etch stop layer 814 away from the first deck substructure 812, is stacked with the first deck substructure 812 in the first direction X, and has a first region 101 including a plurality of first sacrificial layers 811 and a plurality of first dielectric layers 212 stacked alternately in the first direction and a second region 102 that adjoins the first region 101 and is on a side of the first region 101 of the second deck substructure 813 in the second direction Y. The first deck substructure 812 and the second deck substructure 813 together form the first deck structure 810.

In the present operation, the first dielectric layers 212 and the first sacrificial layers 811 may be formed alternately on the first deck substructure 812 through a deposition process to form the second deck substructure 813.

In the present implementation, the operation of forming the first deck structure 810 includes forming the first deck substructure 812, the second deck substructure 813 and so on, so that the first deck structure 810 can include more deck substructures. The present implementation is explained with an example, in which the first deck structure 810 includes the first deck substructure 812 and the second deck substructure 813.

Referring to FIGS. 11 and 14, after formation of the first deck structure 810, the method further includes: forming a first isolation layer 260 extending through the second region 102 of the first deck structure 810 in the first direction X.

It is to be noted that the second region 102 of the first deck structure 810 includes third dielectric layers 241 and fourth dielectric layers 242 stacked alternately in the first direction X. Here, the third dielectric layers 241 and the first sacrificial layers 811 may be film layers formed by performing a patterning process once. The fourth dielectric layers 242 and the first dielectric layers 212 may be film layers formed by performing a patterning process once. The patterning process refers to a process capable of forming at least one pattern of a certain shape. For example, a thin film is formed on a base substrate through any of various film forming processes such as deposition, coating, sputtering and the like, and then patterned to form a film layer including at least one pattern, which is called as a pattern layer. The operation of patterning includes coating of photoresist, exposure, developing, etching, and stripping of the photoresist. In an example, the third dielectric layers 241 and the first sacrificial layers 811 may include the same material. Silicon nitride may be deposited through a deposition process to form the first sacrificial layers 811 in the first region 101 and the third dielectric layers 241 in the second region 102 simultaneously, and silicon oxide may be deposited through a deposition process to form the first dielectric layers 212 in the first region 101 and the fourth dielectric layers 242 in the second region 102 simultaneously.

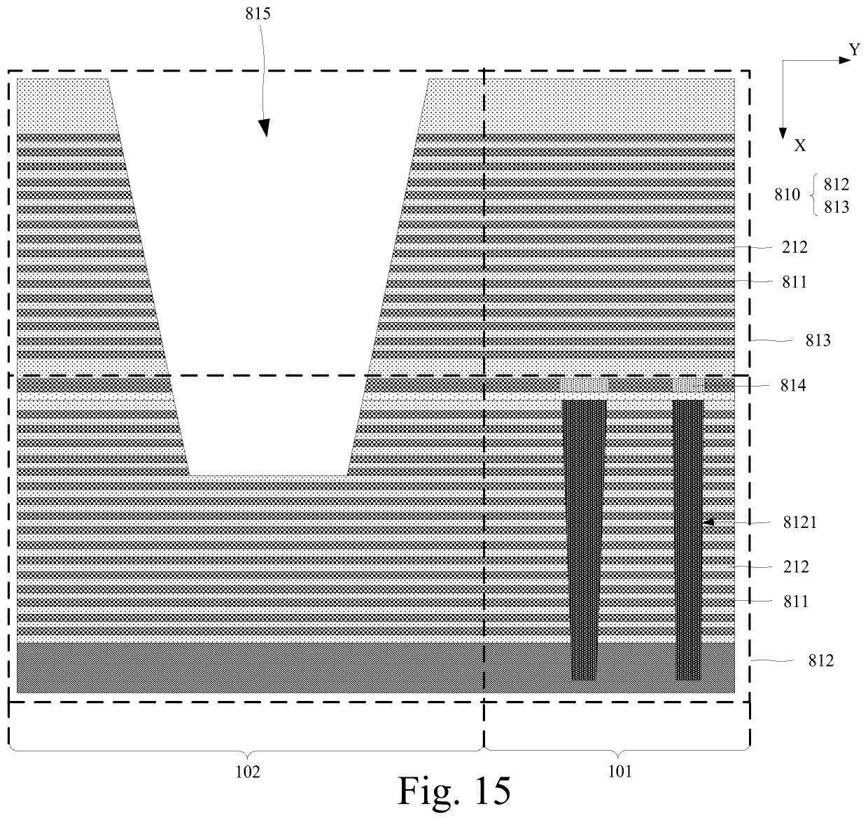

In the present operation, with reference to FIGS. 14 and 15, forming the first isolation layer 260 includes: forming a first recess 815 by a wet etching process or a dry etching process, wherein the first recess 815 is located in the second region 102 of the first deck structure 810 and extends partially through the first deck structure 810 in the first direction X, at least one third dielectric layer 241 is connected with the first sacrificial layer 811, and the first recess 815 extends to a third dielectric layer 241.

Referring to FIGS. 15, 16 and 17, after formation of the first recess 815, the method further includes: forming a first isolation sublayer 261 covering a sidewall of the first recess 815.

In the present operation, an isolation material may be deposited in the first recess 815 by using one or more of thin film deposition processes including, but not limited to, PVD, CVD and ALD. For example, the isolation material may be any one of silicon oxide, silicon nitride, and an insulating material with a high dielectric constant, or any combination thereof, or may be any other isolation material. After deposition of the isolation material in the first recess 815, the isolation material at the bottom of the first recess 815 and the fourth dielectric layer 242 at the bottom of the first recess 815 may be removed to form the first isolation sublayer 261 covering a sidewall of the first recess 815 and exposing a third dielectric layer 241.

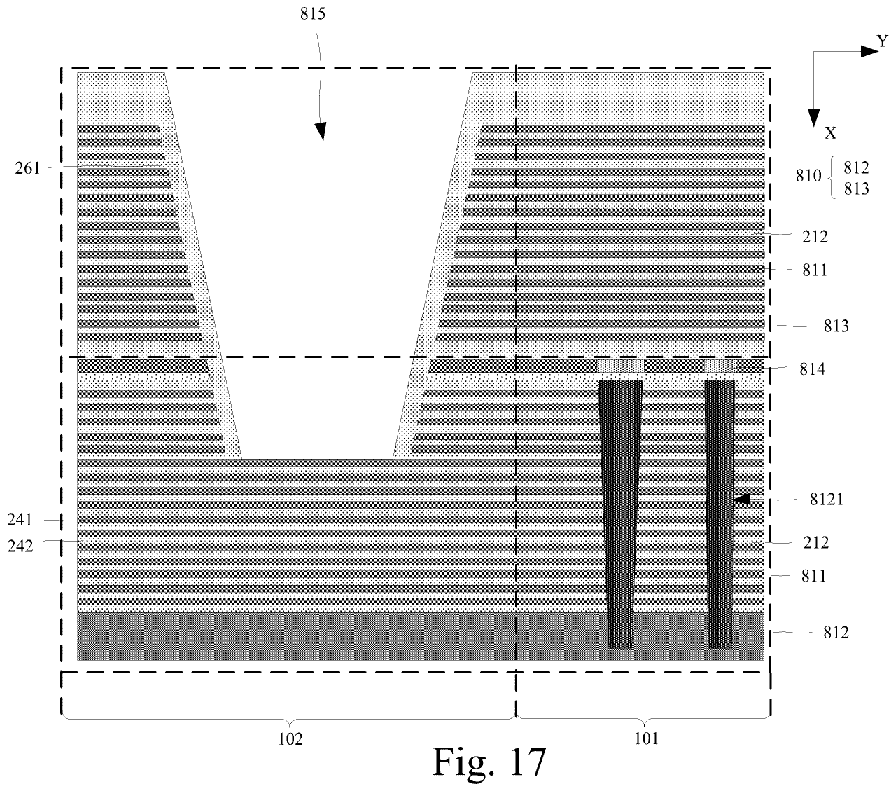

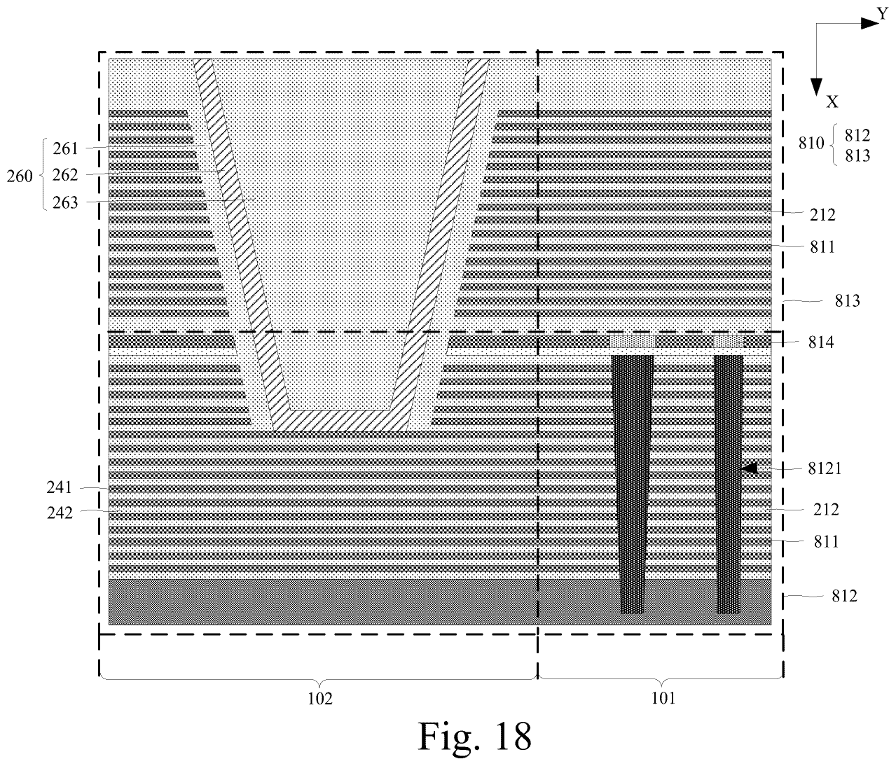

Referring to FIGS. 17 and 18, after formation of the first isolation sublayer 261, the method further includes: forming a second isolation sublayer 262 that covers the bottom of the first recess 815 and is in contact a third dielectric layer 241 and also covers a side of the first isolation sublayer 261.

In the present operation, an isolation material may be deposited in the first recess 815 to form the second isolation sublayer 262 by using one or more of thin film deposition processes including, but not limited to, PVD, CVD and ALD.

With continued reference to FIGS. 17 and 18, after formation of the second isolation sublayer 262, the method further includes: forming a third isolation sublayer 263 covering the second isolation sublayer 262 in the first recess 815, wherein the first isolation sublayer 261, the second isolation sublayer 262 and the third isolation sublayer 263 together form the first isolation layer 260.

In the present operation, an isolation material may be deposited in the first recess 815 to form the third isolation sublayer 263 by using one or more of thin film deposition processes including, but not limited to, PVD, CVD and ALD. The third isolation sublayer 263 fills up the rest of the first recess 815 and has its surface flush with the surface of the second stack substructure 2102.

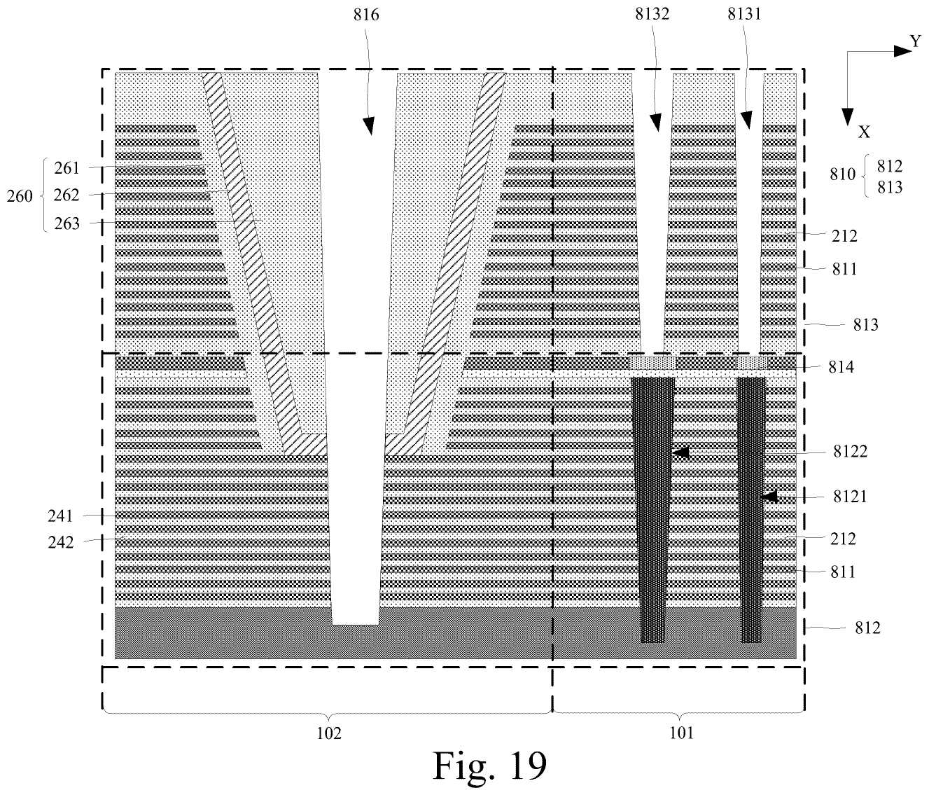

Referring to FIGS. 18 and 19, after formation of the first isolation layer 260, the method further includes: removing a part of the first deck structure 810 to form a plurality of first connection holes 816 located in the second region 102 of the first deck structure 810.

In the present operation, removing a part of the first deck structure 810 includes: removing also a part of the first isolation layer 260 to form a plurality of first connection holes 816, a second channel hole 8131, and a second gate slit 8132 with the second channel hole 8131 extending through the second deck substructure 813 to a side of the etch stop layer 814 away from the first channel hole 8121, and the second gate slit 8132 extending through the second deck substructure 813 to a side of the etch stop layer 814 away from the first gate slit 8122. The plurality of first connection holes 816, second channel hole 8131 and second gate slit 8132 are formed in the same operation and when the second channel hole 8131 extends through the second deck substructure 813 to the etch stop layer 814, the first connection holes 816 extend through the first deck structure 810.

Since the first deck structure 810 is a deck structure formed by layers of different materials stacked alternately, the etching rate of the first deck structure 810 is different from that of the first isolation layer 260. The relationship in amplitude between the etching rates of the first isolation layer 260 and the third stack structure 240 has two instances. In the first one, the etching rate of the first isolation layer 260 is smaller than that of the third stack structure 240, and in the second one, the etching rate of the first isolation layer 260 is larger than that of the third stack structure 240.

Therefore, in the present operation, the plurality of first connection holes 816 may be designed to have different apertures according to the above-mentioned two instances.

In case that the etching rate of the first isolation layer 260 is smaller than that of the third stack structure 240, when the thickness of the first isolation layer 260 is relatively large in the first direction X, the first connection hole 816 needs to extend through more of the first isolation layer 260 and extend through less of the first deck structure 810, the first connection hole 816 extending through the first isolation layer 260 is designed to have a larger aperture; and when the thickness of the first isolation layer 260 is relatively thin in the first direction X, the first connection hole 816 needs to extend through less of the first isolation layer 260 and extend through more of the first deck structure 810, the first connection hole 816 extending through the first isolation layer 260 has a smaller aperture.

In case that the etching rate of the first isolation layer 260 is larger than that of the third stack structure 240, when the thickness of the first isolation layer 260 is relatively large in the first direction X, the first connection hole 816 needs to extend through more of the first isolation layer 260 and extend through less of the first deck structure 810, the first connection hole 816 extending through the first isolation layer 260 is designed to have a smaller aperture; and when the thickness of the first isolation layer 260 is relatively thin in the first direction X, the first connection hole 816 needs to extend through less of the first isolation layer 260 and extend through more of the first deck structure 810, the first connection hole 816 extending through the first isolation layer 260 has a larger aperture.

For different instances, the first connection hole 816 is designed to have a different aperture in a different etching environment, so that in the same etching operation, when the second channel hole 8131 extends to the etch stop layer 814, the plurality of first connection holes 816 may extend through the first deck structure 810. As such, the plurality of first connection holes 816, the second channel hole 8131 and the second gate slit 8132 may be formed simultaneously in one operation, which is advantageous for the simplification of fabrication operations, reducing fabrication costs and improving the fabrication efficiency.

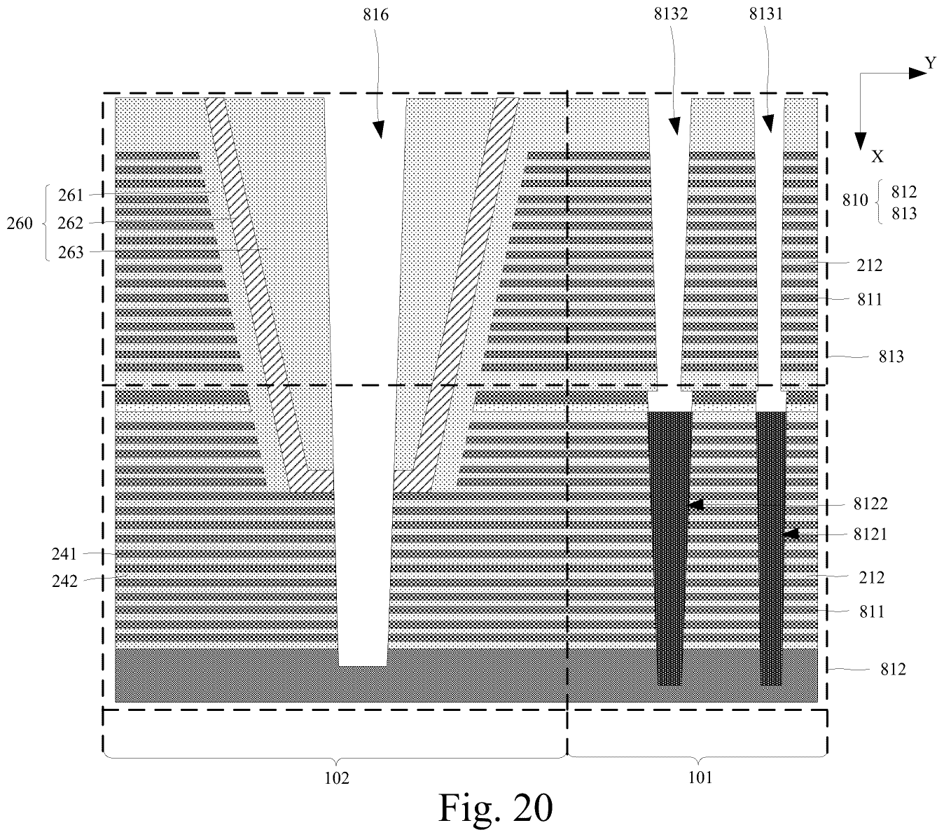

Referring to FIGS. 19 and 20, after formation of the first connection holes 816 and the second channel hole 8131, the method further includes: removing the etch stop layer 814 to make the first channel hole 8121 and the second channel hole 8131 be in communication with each other and the first gate slit 8122 and the second gate slit 8132 be in communication with each other.

In the present operation, for example, the etch stop layer 814 may be removed using a wet etching process or a dry etching process to facilitate the formation of channel structures in the first channel hole 8121 and the second channel hole 8131 during a subsequent fabrication operation.

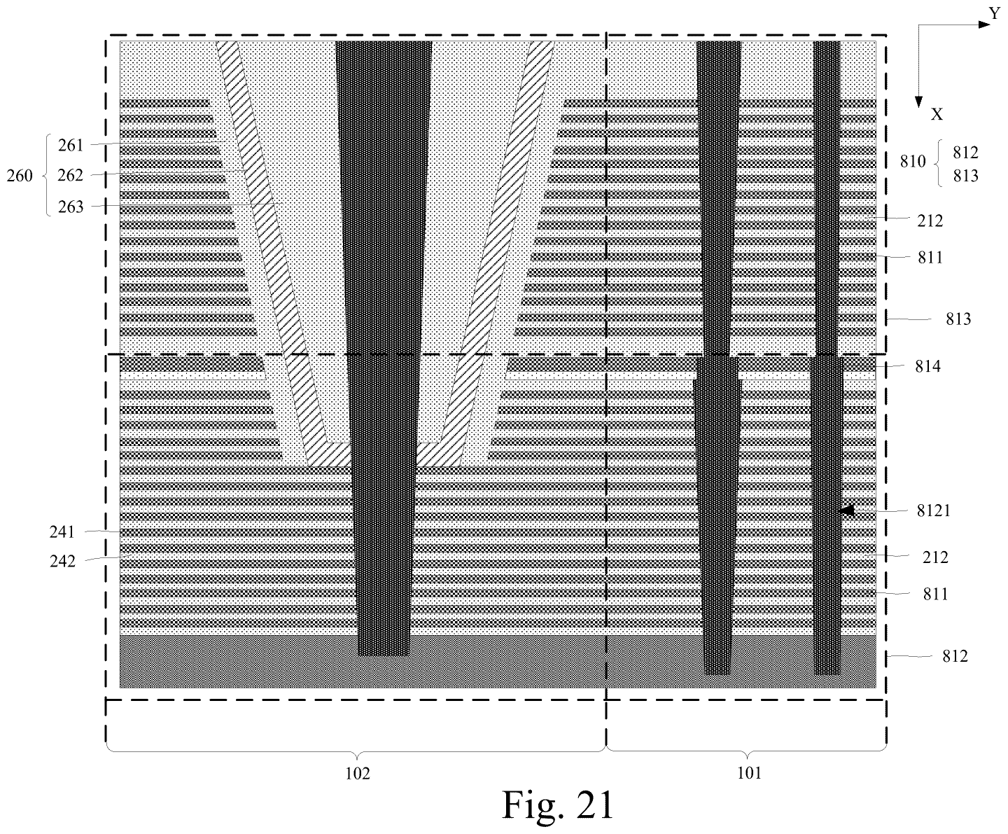

Referring to FIGS. 20 and 21, after removing the etch stop layer 814, the method further includes depositing a sacrificial material (for example, carbon) in the first connection holes 816 and the second channel hole 8131 to facilitate the formation of the second deck structure 820 on the first deck structure 810 during a subsequent operation.

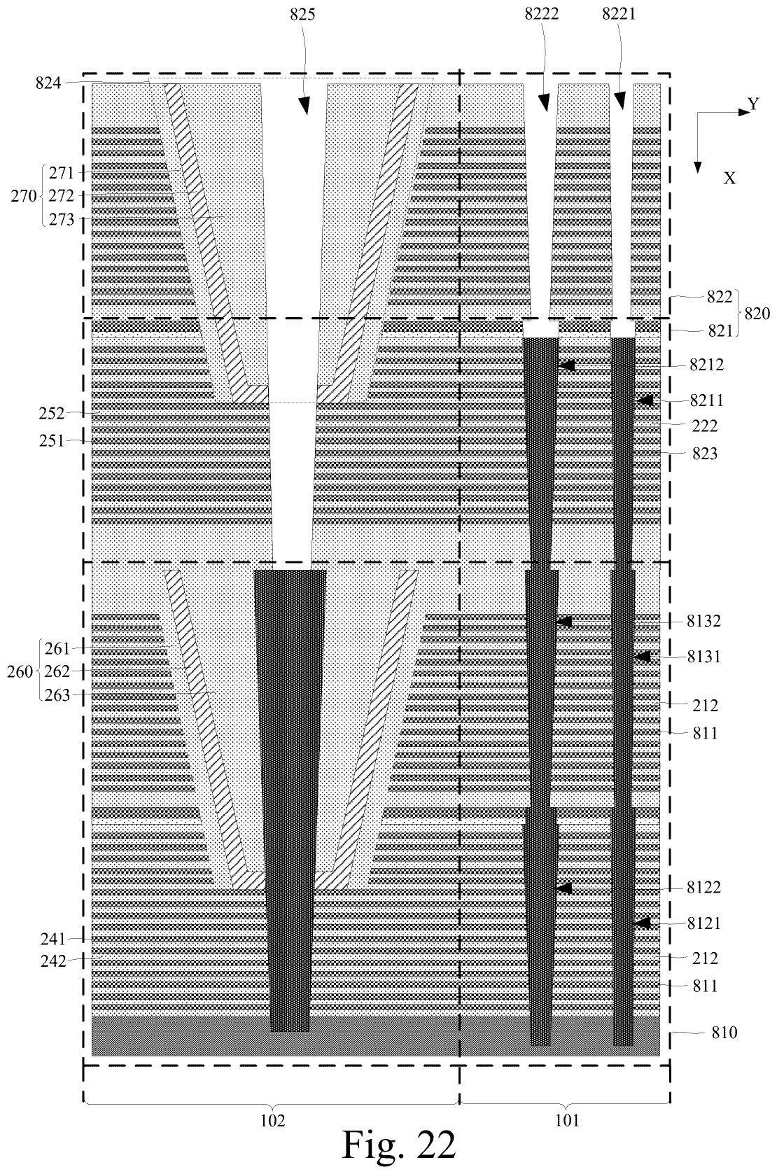

Referring to FIGS. 21 and 22, after depositing a sacrificial material in the first connection holes 816 and the second channel hole 8131, the method further includes: forming a second deck structure 820 stacked with the first deck structure 810 in the first direction X and having a first region 101 including a plurality of second sacrificial layers 823 and a plurality of second dielectric layers 222 stacked alternately in the first direction X and a second region 102 that adjoins the first region 101 and is on a side of the first region 101 of the second deck structure 820 in the second direction.

In the present operation, for example, the second dielectric layers 222 and the second sacrificial layers 823 may be formed alternately on the first deck structure 810 to form the second deck structure 820 by using one or more thin film deposition processes including, but not limited to, PVD, CVD and ALD.

In some implementations, the operation of forming the second deck structure 820 may include: forming a third deck substructure 821 and a fourth deck substructure 822 stacked in the first direction X; and after formation of the third deck substructure 821, removing a part of the third deck substructure 821 to form a third channel hole 8211 and a third gate slit 8212 both located in the first region of the third deck substructure 821, wherein the third channel hole 8211 extends through the third deck substructure 821 to the second channel hole 8131 and the third gate slit 8212 extends through the third deck substructure 821 to the second gate slit 8132. The third gate slit 8212 is in communication with the second gate slit 8132, while the third channel hole 8211 is in communication with the second channel hole 8131. Before formation of the fourth deck substructure 822, the method further includes forming an etch stop layer 814 on the third channel hole 8211 and the third gate slit 8212. The above-described fabrication method of the first deck substructure 812, the first channel hole 8121 and the second deck substructure 813 may be referred to for the fabrication process of the third deck substructure 821, the third channel hole 8211 and the fourth deck substructure 822. In a similar way, more deck substructures may be formed subsequently in the second deck structure 820. The present implementation is explained with an example, in which the second deck structure 820 includes the third deck substructure 821 and the fourth deck substructure 822.

With continued reference to FIGS. 21 and 22, after formation of the second deck structure 820, the method further includes: forming a second recess 824 located in the second region 102 of the second deck structure 820 and extending partially through the second deck structure 820 in the first direction X, wherein at least one fifth dielectric layer 251 is connected with the corresponding second sacrificial layer 823 and the second recess 824 extends to the fifth dielectric layer 251.

It is to be noted that the second region 102 of the second deck structure 820 includes fifth dielectric layers 251 and sixth dielectric layers 252 stacked alternately in the first direction X. Here, the fifth dielectric layers 251 and the second sacrificial layers 823 may be film layers formed by performing a patterning process once. The sixth dielectric layers 252 and the second dielectric layers 222 may be film layers formed by performing a patterning process once. In an example, the fifth dielectric layers 251 and the second sacrificial layers 823 may include the same material. Silicon nitride may be deposited through a deposition process to form the first sacrificial layers 811 in the first region 101 and the fifth dielectric layers 251 in the second region 102 simultaneously, and silicon oxide may be deposited through a deposition process to form the second dielectric layers 222 in the first region 101 and the sixth dielectric layers 252 in the second region 102 simultaneously.

In the present operation, a part of the second deck structure 820 may be removed by, for example, a wet etching process or a dry etching process to form the second recess 824. The second recess 824 extending to the fifth dielectric layer 251 may be understood as the second recess 824 exposing the fifth dielectric layer 251 in the first direction X.

With continued reference to FIG. 22, after formation of the second recess 824, the method further includes: forming a fourth isolation sublayer 271 covering a sidewall of the second recess 824.

In the present operation, the fourth isolation sublayer 271 may be formed by depositing an insulating material in the second recess 824 using one or more thin film deposition processes including, but not limited to, PVD, CVD and ALD and removing the insulating material at the bottom of the second recess 824 with the insulating material remaining at a sidewall of the second recess 824.

With continued reference to FIG. 22, after formation of the fourth isolation sublayer 271, the method further includes: forming a fifth isolation sublayer 272 that covers the bottom of the second recess 824 and the fourth isolation sublayer 271 and is in contact with the fifth dielectric layer 251.

In the present operation, for example, an insulating material may be deposited in the second recess 824 to form the fifth isolation sublayer 272 by using one or more of thin film deposition processes including, but not limited to, PVD, CVD and ALD.

With continued reference to FIG. 22, after formation of the fifth isolation sublayer 272, the method further includes: forming a sixth isolation sublayer 273 covering the fifth isolation sublayer 272 in the second recess 824, wherein the fourth isolation sublayer 271, the fifth isolation sublayer 272 and the sixth isolation sublayer 273 together form the second isolation layer 270.

In the present operation, for example, an insulating material may be deposited in the second recess 824 to form the fifth isolation sublayer 272 by using one or more of thin film deposition processes including, but not limited to, PVD, CVD and ALD. The fifth isolation sublayer 272 fills up the rest space of the second recess 824 and has it upper surface flush with the surface of the second deck structure 820.

With continued reference to FIG. 22, after formation of the second isolation layer 270, the method further includes: removing a part of the second deck structure 820 to form a plurality of second connection holes 825 extending through the second region 102 of the second deck structure 820, wherein one second connection hole 825 and one first connection hole 816 together form one connection hole 830.

In the present operation, removing a part of the second deck structure 820 includes: removing also a part of the second isolation layer 270 to form a plurality of second connection holes 825, a fourth gate slit 8222 and a fourth channel hole 8221 with the fourth channel hole 8221 extending through the fourth deck substructure 822 to a side of the etch stop layer 814 away from the third channel hole 8211 and the fourth gate slit 8222 extending through the fourth deck substructure 822 to a side of the etch stop layer 814 away from the third gate slit 8212. The plurality of second connection holes 825, fourth channel hole 8221 and fourth gate slit 8222 are formed in the same operation and when the fourth channel hole 8221 extends through the second deck substructure 813 to the etch stop layer 814, the second connection holes 825 extend through the second deck structure 820.

In an example, the fabrication process of the first connection holes 816 and the second channel hole 8131 may be referred to for the way, in which an aperture of the second connection hole 825 is designed to enable the second connection holes 825 and the fourth channel hole 8221 to be formed simultaneously in one operation. No repetition will be made here.

After formation of the second connection holes 825, the fourth channel hole 8221 and the fourth gate slit 8222, the method further includes: removing the etching stop layer 814 on the third channel hole 8211 and the third gate slit 8212. For example, the etch stop layer 814 may be removed by using a wet etching process or a dry etching process.

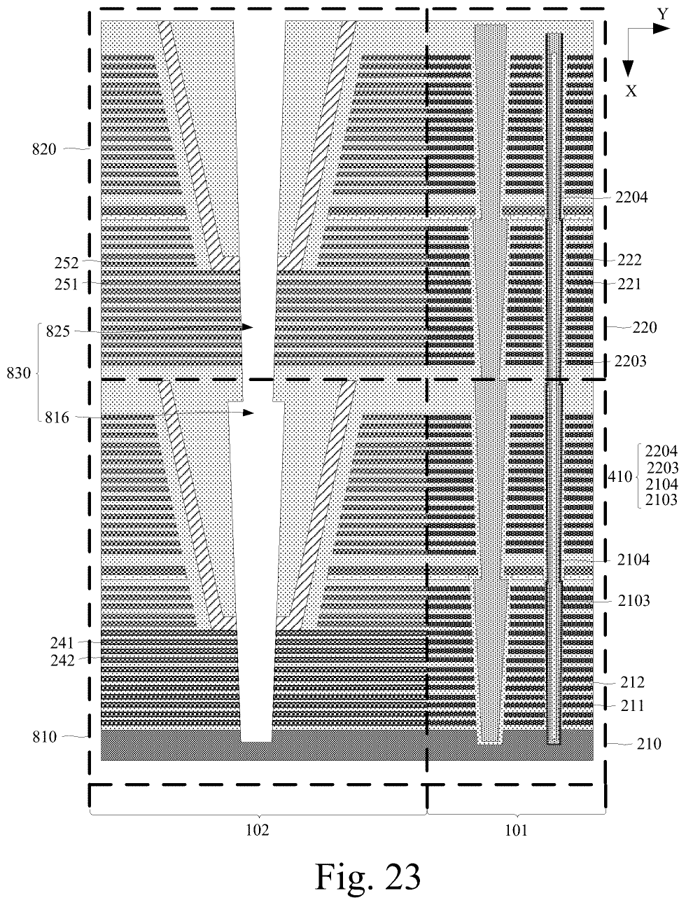

Referring to FIGS. 22 and 23, after removing the etch stop layer 814 on the third channel hole 8211 and the third gate slit 8212, the method further includes: removing the sacrificial material in the first connection holes 816, the first channel hole 8121, the second channel hole 8131, the third channel hole 8211, the first gate slit 8122, the second gate slit 8132 and the third gate slit 8212. In an example, when the sacrificial material includes carbon, the process for removing the sacrificial material in the first connection holes 816, the first channel hole 8121, the second channel hole 8131, the third channel hole 8211, the first gate slit 8122, the second gate slit 8132 and the third gate slit 8212 may include performing an ashing processing to remove all of the sacrificial material

Through the above-described operation, the first channel hole 8121, the second channel hole 8131, the third channel hole 8211 and the fourth channel hole 8221 are in communication with each other, and they together form a channel hole 850. The first gate slit 8122, the second gate slit 8132, the third gate slit 8212 and the fourth gate slit 8222 are in communication with each other, and they together form a gate slit 840.

With continued reference to FIG. 23, after removing all of the sacrificial material, the method further includes: forming a channel structure in the channel hole. The channel structure in the first channel hole 8121 is a first channel structure 2103 and the channel structure in the second channel hole 8131 is a second channel structure 2104.

In the present operation, for example, silicon oxide, silicon nitride, silicon oxide and polysilicon material may be deposited sequentially in the channel hole 850 by using a deposition process to form channel structures 410.

With continued reference to FIG. 23, after formation of the first channel structure 2103 in the first channel hole 8121 and the second channel structure 2104 in the second channel hole 8131, the method further includes: replacing the first sacrificial layers 811 with the first gate layers 211 and replacing the second sacrificial layers 823 with the second gate layers 221.

In the present operation, for example, the first sacrificial layers 811 and the second sacrificial layers 823 may be removed via the gate slit 840 by using a wet etching process; and then by using a deposition process, the first gate layers 211 may be formed where the first sacrificial layers 811 were located and the second gate layers 221 may be formed where the second sacrificial layers 823 were located, so as to achieve a gate replacement. The first region 101 of the first deck structure 810 forms the first stack structure 210 and the second region 102 of the second deck structure 820 forms the second stack structure 220.

In operation S2, a plurality of connection structures are formed. The connection structure includes: a connection post, at least one first connection layer and at least one second connection layer. The connection post is located on a side of the first stack structure and the second stack structure in the second direction. The first connection layer is parallel to the second direction and one of the at least one first connection layer connects the connection post with one of the first gate layers. The second connection layer is parallel to the second direction and one of the at least one second connection layer connects the connection post with one of the second gate layers. The second direction crosses the first direction. In a reference plane parallel to the second direction, at least two of the connection structures have their respective connection posts of different sizes.

In the present operation, with reference to FIGS. 23, 24 and 11, forming a connection structure 230 in a connection hole 830 includes: removing a part of the second isolation sublayer 262 at the bottom of the first recess 815 and a part of the fifth isolation sublayer 272 at the bottom of the second recess 824 to form a first recess space 817 in communication with the first connection hole 816 and a second recess space 826 in communication with the second connection hole 825.

In the present operation, the second isolation sublayer 262 and the fifth isolation sublayer 272 may include the same material, which, however, is different from the materials of other structures. The part of the second isolation sublayer 262 at the bottom of the first recess 815 and the part of the fifth isolation sublayer 272 at the bottom of the second recess 824 may be removed by a selective etching liquid.

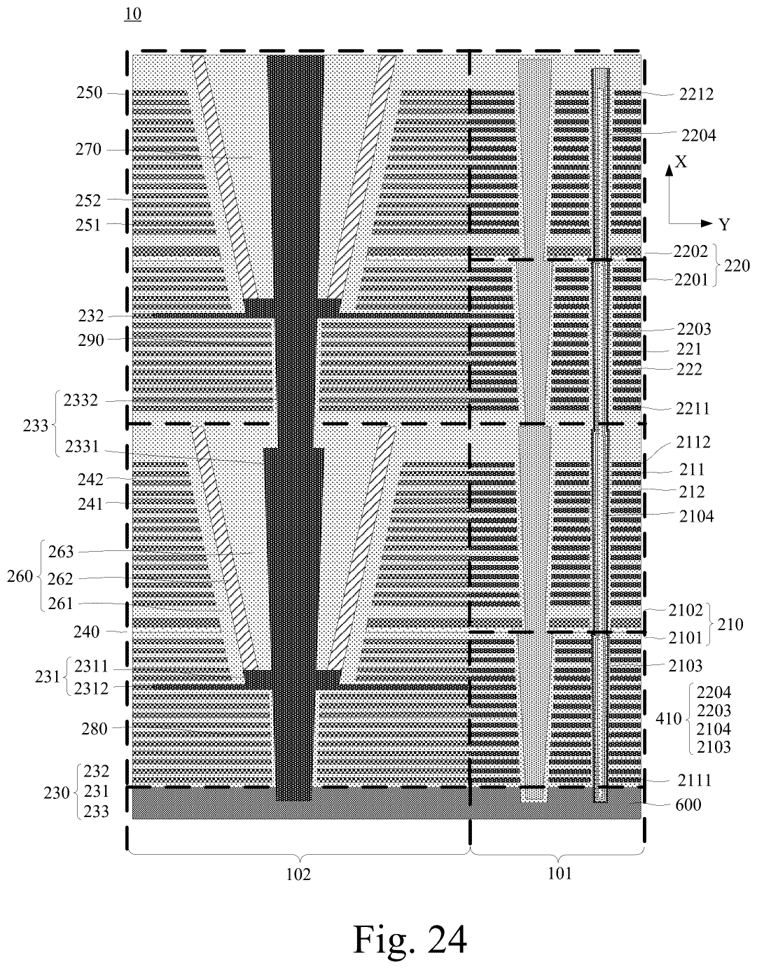

With reference to FIGS. 23 and 24, before removing the part of the second isolation sublayer 262 at the bottom of the first recess 815 and the part of the fifth isolation sublayer 272 at the bottom of the second recess 824, the method further includes: removing a part of the third dielectric layers 241 and a part of the fifth dielectric layers 251 to form a third recess space 818 in communication with the first connection hole 816 and a fourth recess space 827 in communication with the second connection hole 825. A third isolation layer 280 is formed in the third recess space 818 and a fourth isolation layer 290 is formed in the fourth recess space 827 to protect the third dielectric layer 241 and the fifth dielectric layer 251 from being damaged during the subsequent etching process.

For example, a part of the third dielectric layer 241 and a part of the fifth dielectric layer 251 may be removed by a wet etching process.

As shown in FIGS. 11, 23 and 24, after formation of the first recess space 817 and the second recess space 826, the method further includes: removing a part of the third dielectric layer 241 exposed in the first recess space 817 and a part of the fifth dielectric layer 251 exposed in the second recess space 826 to form a first space 819 to be filled in communication with the first recess space 817 and a second space 828 to be filled in communication with the second recess space 826.

In the present operation, for example, a part of the third dielectric layer 241 exposed in the first recess space 817 and a part of the fifth dielectric layer 251 exposed in the second recess space 826 may be removed by using a wet etching process.

As shown in FIGS. 11, 23 and 24, after formation of the first space 819 to be filled and the second space 828 to be filled, the method further includes: filling a conductive material into a plurality of connection holes 830 to form a plurality of connection structures 230, wherein a part of the conductive material filled in the connection holes 830 forms the connection posts 233, a part of the conductive material filled in the first space 819 to be filled forms the first connection layer 231, and a part of the conductive material filled in the second space 828 to be filled forms the second connection layer 232.

In the present operation, for example, the conductive material may be filled in the plurality of connection holes 830 to form the plurality of connection structures 230 by using one or more of thin film deposition processes including, but not limited to, PVD, CVD and ALD. The conductive material includes, but not limited to, any one of tungsten (W), cobalt (Co), copper (Cu), aluminum (Al), polysilicon, doped silicon, and silicide, or any combination thereof, or may be any other suitable conductive material.

In the memory device 10 formed by the fabrication method described above, even though more stack structures are formed, the number of the connection structures 230 will not be increased. Therefore, in the memory device 10 formed by the fabrication method described above, the footprint occupied by the connection structures 230 will not be increased as the number of the stack structures increases, which is advantageous for the improvement in the storage density of the memory device 10 and the development of the memory device 10 toward a larger capacity and a smaller volume.

Furthermore, in order to improve the capacity of the memory device 10 in the art, the number of the stack structures is increased and thus the number of the SD devices is also increased, but in order to control the dimensions of the memory device 10, the dimensions of the SD device need to be reduced. However, since the connection structure 230 obtained by the fabrication method in the present implementation connects one gate layer in each of a plurality of stack structures and one SD device, the number of SD devices will not increase and therefore the need for reducing the dimensions of the SD devices can be alleviated.

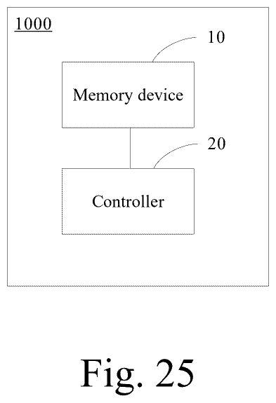

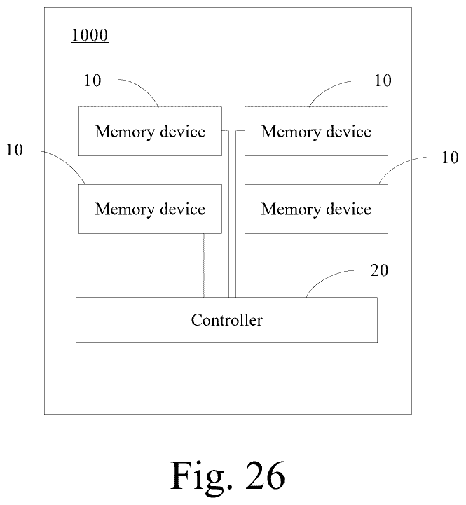

FIG. 25 is a block diagram of a memory system in accordance with some implementations. FIG. 26 is a block diagram of a memory system in accordance with some other implementations. Referring to FIGS. 25 and 26, some implementations of the present disclosure further provide a memory system 1000 including a controller 20 and the memory device 10 provided in some implementations above. Here, the controller 20 is coupled with the memory device 10 to control its data storage.

The memory system 1000 can be integrated into various types of storage devices, for example, be included in the same package, such as a universal flash storage (UFS) package or an embedded multi-media card (eMMC) package. That is, the memory system 1000 may be applied to and packaged into various electronic products such as a mobile phone (e.g., a cellphone), a desktop computer, a tablet computer, a laptop computer, a server, a vehicle-mounted device, a gaming console, a printer, a positioning device, a wearable device, a smart sensor, a mobile power source, a virtual reality (VR) device, an augmented reality (AR) device, or any other suitable electronic device having storage therein.

In some implementations, referring to FIG. 25, the memory system 1000 includes a controller 20 and a memory device 10 and may be integrated into a memory card. In an example, the memory device 10 may be a memory having a three-dimensional structure (3D NAND).

The memory card may include any one of a PC card (the personal computer memory card international association, PCMCIA), a compact flash (CF) card, a smart media (SM) card, a memory stick, a multimedia card (MMC), a secure digital memory card (an SD device) and a UFS.

In some other implementations, with reference FIG. 26, the memory system 1000 includes a controller 20 and a plurality of memory devices 10 and is integrated into a solid-state drive (an SSD device).

In the memory system 1000, in some implementations, the controller 20 is configured to operate in a low duty-cycle environment like an SD device card, a CF card, a universal serial bus (USB) flash drive or any other medium for use in an electronic device, such as a personal computer, a digital camera, a mobile phone, etc.

In some other implementations, the controller 20 is configured to operate in a high duty-cycle environment like an SSD device or an eMMC, used as a data storage for a mobile device such as a smart phone, a tablet computer or a laptop computer, and an enterprise storage array.

In some implementations, the controller 20 is configured to manage the data stored in the memory device 10 and communicates with an external device (e.g., a host). In some implementations, the controller 20 can be control operations of the memory device 10, such as read, erase, and program operations. In some implementations, the controller 20 can also be configured to manage various functions with respect to the data stored or to be stored in the memory device 10, including at least one of bad-block management, garbage collection, logical-to-physical address conversion and wear leveling. In some implementations, the controller 20 is further configured to process error correction codes (ECCs) with respect to the data read from or written to the memory device 10.

Of course, the controller 20 may also perform any other suitable functions, for example, formatting the memory device 10; and for example, the controller 20 can communicate with an external device (e.g., a host) according to at least one of various interface protocols.

It is to be noted that the interface protocol includes at least one of a USB protocol, an MMC protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESD device I) protocol, an integrated drive electronics (IDE) protocol, and a Firewire protocol.

The controller 20 in the implementations above may be a central processing unit (CPU), a general-purpose processor, a digital signal processor (DSP), an application-specific integrated circuit (ASIC), a field programmable gate array (FPGA) or another programmable logic device, a transistor logic device, a hardware component or any combinations thereof.

In the present implementation, the memory system 1000 includes the memory device 10 provided in some implementations above, which facilitates improvement of the memory density of the memory system 1000.

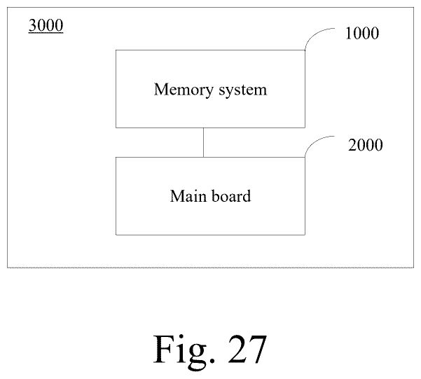

Some implementations of the present disclosure further provide an electronic apparatus. FIG. 27 is a block diagram of an electronic apparatus in accordance with some implementations. As shown in FIG. 27, the electronic apparatus 3000 includes a main board 2000 and a memory system 1000 provided in some implementations above. Here, the main board 2000 is electrically connected with the memory system 1000. Furthermore, the electronic apparatus 3000 may further include any one of a central processing unit (CPU) and a cache.

In an example, the electronic apparatus 3000 may be any one of a cellphone, a desktop computer, a tablet computer, a laptop computer, a server, a vehicle-mounted device, a wearable device (e.g., a smart watch, a smart bracelet, smart glasses), a mobile power source, a gaming console and a digital multimedia player.

In the present implementation, the electronic apparatus 3000 may include the memory system 1000 provided in some implementations above, which is advantageous for the improvement in the memory density of the electronic apparatus 3000 and the development of the electronic apparatus 3000 towards a larger capacity and a smaller volume.

What have been described above are only specific implementations of the present disclosure and the scope claimed by the present disclosure is not limited thereto. Variations or substitutions that easily occur to those skilled in the art without departing from the scope of the present disclosure should be covered by the scope claimed by the present disclosure. Therefore, the scope of the present disclosure should be determined by the scope of the claims.

What is claimed is:

1. A memory device, comprising:
a first stack structure comprising a plurality of first gate layers and a plurality of first dielectric layers stacked alternately in a first direction;
a second stack structure comprising a plurality of second gate layers and a plurality of second dielectric layers stacked alternately in the first direction, wherein the second stack structure and the first stack structure are stacked in the first direction; and
a plurality of connection structures comprising a connection post, at least one first connection layer and at least one second connection layer,
wherein the connection post is located on a side of the first stack structure and the second stack structure in a second direction crossing the first direction, the first connection layer is parallel to the second direction, one of the at least one first connection layer connects the connection post with one of the first gate layers, the second connection layer is parallel to the second direction, and one of the at least one second connection layer connects the connection post with one of the second gate layers, and
wherein in a reference plane parallel to the second direction, at least two of the connection structures have their respective connection posts of different sizes.

2. The memory device of claim 1, further comprising a channel structure extending through the first stack structure and the second stack structure, wherein
the size of the connection post is larger than that of the channel structure in the reference plane.

3. The memory device of claim 2, wherein the first stack structure comprises a first stack substructure and a second stack substructure stacked in the first direction; and
the channel structure comprises a first channel structure and a second channel structure stacked in the first direction with the first channel structure extending through the first stack substructure and the second channel structure extending through the second stack substructure.

4. The memory device of claim 1, further comprising a third stack structure and a fourth stack structure that are stacked in the first direction and located on a side of the first stack structure and the second stack structure in the second direction, wherein
the connection post extends through the third stack structure and the fourth stack structure;
the third stack structure comprises a plurality of third dielectric layers and a plurality of fourth dielectric layers stacked alternately in the first direction with at least one of the third dielectric layers connected with the at least one first connection layer; and
the fourth stack structure comprises a plurality of fifth dielectric layers and a plurality of sixth dielectric layers stacked alternately in the first direction with at least one of the fifth dielectric layers connected with the at least one second connection layer.

5. The memory device of claim 4, further comprising:
a plurality of first isolation layers, wherein one of the first isolation layers extends partially through the third stack structure to one of the at least one first connection layer and surrounds one of the connection posts; and
a plurality of second isolation layers, wherein one of the second isolation layers extends partially through the fourth stack structure to one of the at least one second connection layer and surrounds one of the connection posts.

6. The memory device of claim 5, wherein one of the plurality of connection structures is a first connection structure and another one of the plurality of connection structures is a second connection structure; and
in the first direction, the largest size of the first isolation layer surrounding the first connection structure is larger than the largest size of the first isolation layer surrounding the second connection structure, and in the reference plane, the size of the connection post of the first connection structure is larger than the size of the connection post of the second connection structure.

7. The memory device of claim 5, wherein one of the plurality of connection structures is a first connection structure and another one of the plurality of connection structures is a second connection structure; and
in the first direction, the largest size of the first isolation layer surrounding the first connection structure is larger than the largest size of the first isolation layer surrounding the second connection structure, and in the reference plane, the size of the connection post of the first connection structure is smaller than the size of the connection post of the second connection structure.

8. The memory device of claim 6, wherein in the reference plane, a size of the first isolation layer surrounding the first connection structure is larger than a size of the first isolation layer surrounding the second connection structure.

9. The memory device of claim 6, wherein one of the plurality of connection structures is a third connection structure, and the first connection structure, the third connection structure and the second connection structure are arranged in this order in a reference direction crossing the first direction; and in the reference plane, the size of the connection post of the first connection structure is larger than the size of the connection post of the third connection structure and the size of the connection post of the second connection structure is larger than the size of the connection post of the third connection structure.

10. The memory device of claim 6, wherein one of the plurality of connection structures is a third connection structure, and the first connection structure, the third connection structure and the second connection structure are arranged in this order in a reference direction crossing the first direction; and in the reference plane, the size of the connection post of the first connection structure is smaller than the size of the connection post of the third connection structure and the size of the connection post of the second connection structure is smaller than the size of the connection post of the third connection structure.

11. The memory device of claim 5, wherein the connection post comprises a first connection post and a second connection post stacked in the first direction, the first connection post extends through the third stack structure, and the second connection post extends through the fourth stack structure; and
in the second direction, a size of an end of the first connection post proximate to the second connection post is larger than a size of an end of the second connection post proximate to the first connection post.

12. The memory device of claim 11, wherein, in the second direction, the size of the end of the first connection post proximate to the second connection post is larger than a size of an end of the first connection post away from the second connection post; or
in the second direction, a size of an end of the second connection post away from the first connection post is larger than the size of the end of the second connection post proximate to the first connection post.

13. The memory device of claim 5, wherein the first connection layer comprises a first sublayer and a second sublayer stacked in the first direction with the first sublayer located between the first isolation layer and the second sublayer and the first isolation layer surrounding the first sublayer.

14. The memory device of claim 13, wherein the first isolation layer comprises a first isolation sublayer, a second isolation sublayer and a third isolation sublayer;
the first isolation sublayer surrounds the connection post;
the second isolation sublayer is located between the first isolation sublayer and the connection post and surrounds the connection post; and
the third isolation sublayer is located between the second isolation sublayer and the connection post and surrounds the connection post.

15. A method of fabricating a memory device, comprising:
forming a first stack structure and a second stack structure, wherein the first stack structure comprises a plurality of first gate layers and a plurality of first dielectric layers stacked alternately in a first direction and the second stack structure comprises a plurality of second gate layers and a plurality of second dielectric layers stacked in the first direction with the second stack structure and the first stack structure stacked in the first direction; and
forming a plurality of connection structures comprising a connection post, at least one first connection layer and at least one second connection layer, wherein the connection post is located on a side of the first stack structure and the second stack structure in a second direction crossing the first direction, the first connection layer is parallel to the second direction, one of the at least one first connection layer connects the connection post with one of the first gate layers, the second connection layer is parallel to the second direction, and one of the at least one second connection layer connects the connection post with one of the second gate layers; and
in a reference plane parallel to the second direction, at least two of the connection structures have their respective connection posts of different sizes.

16. The method of claim 15, wherein forming the first stack structure and the second stack structure comprises:
forming a first deck structure having a first region comprising a plurality of first sacrificial layers and the plurality of first dielectric layers stacked alternately in the first direction and a second region that adjoins the first region and is on a side of the first region of the first deck structure in the second direction crossing the first direction;
removing a part of the first deck structure to form a plurality of first connection holes located in the second region of the first deck structure;
forming a second deck structure stacked with the first deck structure in the first direction and having a first region comprising a plurality of second sacrificial layers and the plurality of second dielectric layers stacked alternately in the first direction and a second region that adjoins the first region and is on a side of the first region of the second deck structure in the second direction;
removing a part of the second deck structure to form a plurality of second connection holes extending through the second region of the second deck structure, wherein one of the second connection holes and one of the first connection holes together form one connection hole; and
replacing the first sacrificial layers with the first gate layers and replacing the second sacrificial layers with the second gate layers.

17. The method of claim 16, wherein forming the first deck structure comprises:
forming a first deck substructure having a first region comprising the plurality of first sacrificial layers and the plurality of first dielectric layers stacked alternately in the first direction and a second region that adjoins the first region and is on a side of the first region of the first deck substructure in the second direction;
removing a part of the first deck substructure to form a first channel hole extending through the first region of the first deck substructure;
forming an etch stop layer stacked with the first channel hole in the first direction; and
forming a second deck substructure stacked with the first deck substructure in the first direction and having a first region comprising the plurality of first sacrificial layers and the plurality of first dielectric layers stacked alternately in the first direction and a second region that adjoins the first region and is on a side of the first region of the second deck substructure in the second direction, wherein the first deck substructure and the second deck substructure together form the first deck structure.

18. The method of claim 17, wherein, after forming the first deck structure and before removing the part of the first deck structure, the method further comprises:
forming a first isolation layer extending partially through the second region of the first deck structure in the first direction; and
removing the part of the first deck structure comprises:
further removing a part of the first isolation layer to form the plurality of first connection holes and a second channel hole, wherein the second channel hole extends through the second deck substructure to the etch stop layer.

19. The method of claim 18, wherein, after forming the plurality of first connection holes and the second channel hole and before forming the second deck structure, the method further comprises:
removing the etch stop layer to make the first channel hole and the second channel hole be in communication with each other.

20. The method of claim 18, wherein forming the first isolation layer comprises:
forming a first recess located in the second region of the first deck structure and extending partially through the first deck structure in the first direction, wherein the second region of the first deck structure comprises a plurality of third dielectric layers and a plurality of fourth dielectric layers stacked alternately in the first direction, at least one of the third dielectric layers is connected with the first sacrificial layer, and the first recess extends to the third dielectric layer;
forming a first isolation sublayer covering a sidewall of the first recess;
forming a second isolation sublayer that covers a bottom of the first recess and is in contact the third dielectric layer and also covers a side of the first isolation sublayer; and
forming a third isolation sublayer in the first recess, the third isolation sublayer covering the second isolation sublayer, wherein the first isolation sublayer, the second isolation sublayer and the third isolation sublayer together form the first isolation layer.
